(19) United States
(12) Patent Application Publication
(10) Pub. No.: US 2025/0359222 A1
(43) Pub. Date: Nov. 20, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 18/664,703

(22) Filed: May 15, 2024

(51) Int. Cl. H01L 29/08; H01L 21/8238; H01L 27/092; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 64/017; H10D 84/017; H10D 84/0172; H10D 84/0184; H10D 84/038; H10D 84/85

(57) ABSTRACT

A method of forming a semiconductor structure includes forming a fin structure including first and second semiconductor layers alternately stacked; forming source/drain trenches in the fin structure; recessing the first semiconductor layers to form inner spacer recesses; and forming first, second, and third inner spacers in the inner spacer recesses. The second inner spacers are vertically sandwiched between the first and third inner spacers. The method further includes recessing the first inner spacers and first portions of the second inner spacers to form recessed first inner spacers and recessed first portions of the second inner spacers; and forming first and second source/drain features in the source/drain trenches. The first source/drain features contact the recessed first inner spacers and the recessed first portions of the second inner spacers. The second source/drain features contact the third inner spacers and second portions of the second inner spacers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been introduced to improve gate control by increasing gate-channel coupling, reducing off-state current, and reducing short-channel effects (SCEs). As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are perspective views of a workpiece at various fabrication stages, in accordance with some embodiments of the present disclosure.

FIGS. 3A, 4A, 5A, 6A, 7A, 8A, 9A, 10A, 11A, 12A, and 15A are Y-Z cross-sectional views of the workpiece at various fabrication stages along line A-A′ of FIG. 2, in accordance with some embodiments of the present disclosure.

FIGS. 4B, 5B, 6B, 7B, 8B, 9B, 10B, 11B, 12B, 13A, 14A, and 15B are X-Z cross-sectional views of the workpiece at various fabrication stages along line B-B′ of FIG. 2, in accordance with some embodiments of the present disclosure.

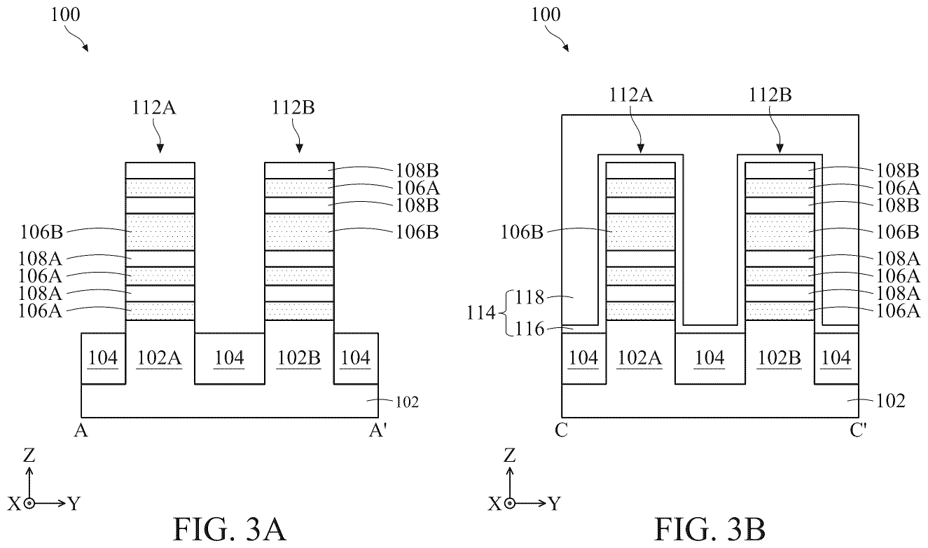

FIGS. 3B, 13B, and 14B are Y-Z cross-sectional views of the workpiece at various fabrication stages along line C-C′ of FIG. 2, in accordance with some embodiments of the present disclosure.

FIGS. 16A, 17A, 18A, 19A, and 20A are Y-Z cross-sectional views of a workpiece at various fabrication stages along line A-A′ of FIG. 2, in accordance with some alternative embodiments of the present disclosure.

FIGS. 16B, 17B, 18B, 19B, and 20B are X-Z cross-sectional views of the workpiece at various fabrication stages along line B-B′ of FIG. 2, in accordance with some alternative embodiments of the present disclosure.

FIG. 21 is a perspective view of a workpiece at a fabrication stage, in accordance with some alternative embodiments of the present disclosure.

FIGS. 22A, 23A, 24A, 25A, and 26A are Y-Z cross-sectional views of the workpiece at various fabrication stages along line A-A′ of FIG. 21, in accordance with some alternative embodiments of the present disclosure.

FIGS. 22B, 23B, 24B, 25B, and 26B are X-Z cross-sectional views of the workpiece at various fabrication stages along line B-B′ of FIG. 21, in accordance with some alternative embodiments of the present disclosure.

FIGS. 27A and 27B are cross-sectional views of a semiconductor structure along lines A-A′ and B-B′ of FIG. 21, respectively, in accordance with some alternative embodiments of the present disclosure.

FIGS. 28A, 29A, 30A, 31A, 32A, and 33A are Y-Z cross-sectional views of a workpiece at fabrication stages along line A-A′ of FIG. 2, in accordance with some alternative embodiments of the present disclosure.

FIGS. 28B, 29B, 30B, 31B, 32B, and 33B are X-Z cross-sectional views of the workpiece at various fabrication stages along line B-B′ of FIG. 2, in accordance with some alternative embodiments of the present disclosure.

FIGS. 34A, 35A, 36A, 37A, 38A, 39A, and 40A are Y-Z cross-sectional views of a workpiece at fabrication stages along line A-A′ of FIG. 2, in accordance with some alternative embodiments of the present disclosure.

FIGS. 34B, 35B, 36B, 37B, 38B, 39B, and 40B are X-Z cross-sectional views of the workpiece at various fabrication stages along line B-B′ of FIG. 2, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional CFETs with GAA structures. Generally, a CFET may include an n-type FET (NFET) and a p-type FET (PFET) disposed vertically with a plurality of vertically stacked nanostructures (e.g., nanosheets, nanowires, or nanorods) in a channel region of the CFET, thereby allowing better gate control, lowered leakage current, and improved scaling capability for various IC applications.

The GAA structures may be patterned by any suitable method. For example, the GAA structures may be patterned using one or more photolithography processes, including double-patterning or multi-patterning processes. Generally speaking, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and is patterned using a photolithography process. Spacers are formed alongside the patterned sacrificial layer using a self-aligned process. The sacrificial layer is then removed, and the remaining spacers may then be used to pattern the GAA structure.

In CFET device, the vertically disposed PFET and NFET may have different desired performance. For example, one of the PFET and NFET may pursue thinner inner spacers to increase the junction overlap between the metal gate and the epitaxial source/drain feature, thereby obtaining better DC performance. For example, the other one of the PFET and NFET may pursue thicker inner spacers to increase the distance between the metal gate and the epitaxial source/drain feature, thereby obtaining reduced parasitic capacitance. However, in the existing CFET device, the inner spacers of PFET and the inner spacers of NFET have the same thickness. Therefore, a novel structure and fabricating method are needed to provide inner spacers with different thickness for PFET and NFET in the CFET.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures that have thinner inner spacers for one of the PFET and NFET for improving DC performance, and thicker inner spacers for the other one of the PFET and NFET to reduce parasitic capacitance. Moreover, embodiments discussed herein further include methods and structures that have larger inner metal gate width for one of the PFET and NFET to mitigate DIBL (Drain-induced barrier lowering). In this way, the inner spacer thicknesses and the inner metal gate widths of PFET and NFET in the same CFET can be modified individually, and thus can be optimized individually. Furthermore, thickness of the gate spacers can be formed wider than the inner spacers of PFET and NFET to further reduce the parasitic capacitance.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

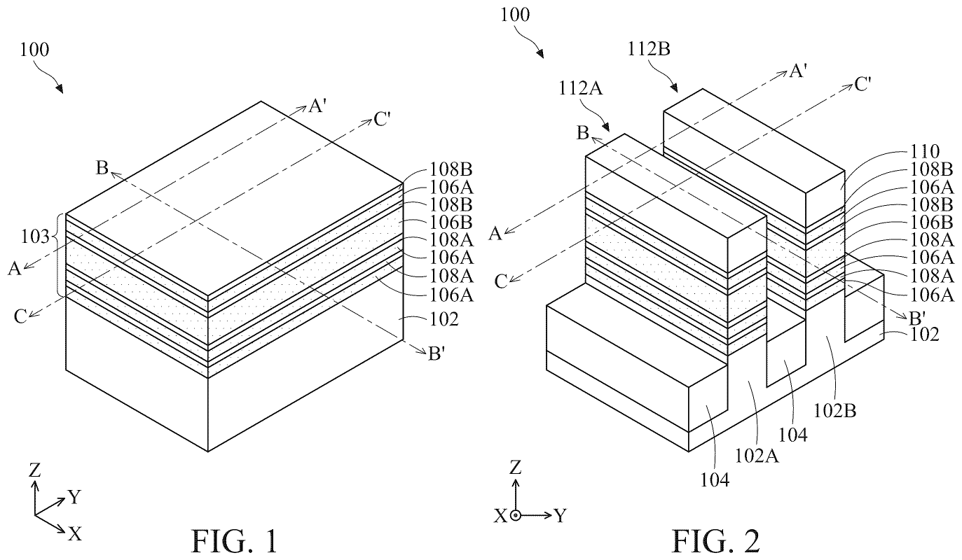

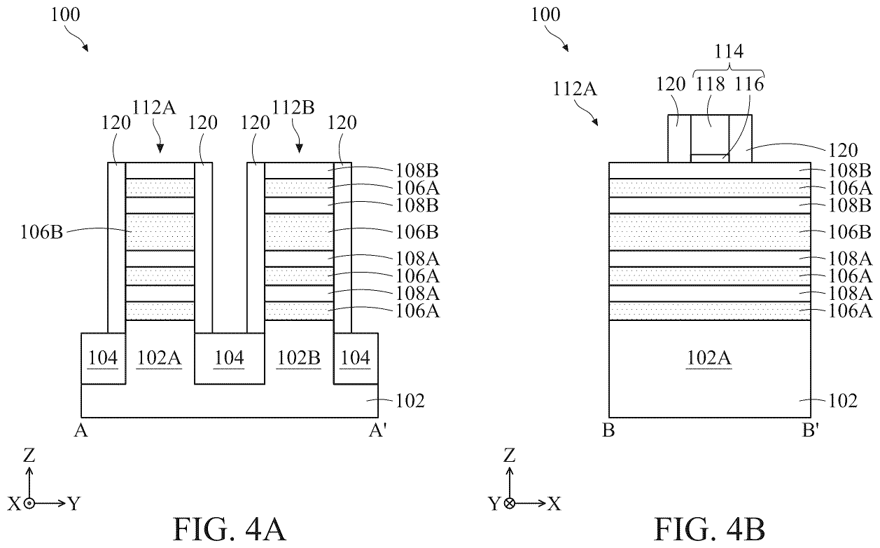

FIGS. 1 and 2 are perspective views of a workpiece 100 at various fabrication stages, in accordance with some embodiments. FIGS. 3A, 4A, 5A, 6A, 7A, 8A, 9A, 10A, 11A, 12A, and 15A are Y-Z cross-sectional views of the workpiece 100 at various fabrication stages along line A-A′ of FIG. 2, in accordance with some embodiments. FIGS. 4B, 5B, 6B, 7B, 8B, 9B, 10B, 11B, 12B, 13A, 14A, and 15B are X-Z cross-sectional views of the workpiece 100 at various fabrication stages along line B-B′ of FIG. 2, in accordance with some embodiments. FIGS. 3B, 13B, and 14B are Y-Z cross-sectional views of the workpiece 100 at various fabrication stages along line C-C′ of FIG. 2, in accordance with some embodiments.

Referring to FIG. 1, the workpiece 100 includes a substrate 102 and a stack 103 over the substrate 102, in accordance with some embodiments. In some embodiments, the substrate 102 contains a semiconductor material, such as bulk silicon (Si). In some embodiments, the substrate 102 may include other semiconductors such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B), indium (In)). The n-type and p-type well regions may be formed by using ion implantation or thermal diffusion. Since the workpiece 100 will be fabricated into a semiconductor structure 100 upon conclusion of the fabrication processes, the workpiece 100 may be referred to as the semiconductor structure 100 as the context requires.

In some embodiments, the stack 103 may include semiconductor layers 106 (including semiconductor layers 106A and a semiconductor layer 106B) and 108 (including semiconductor layers 108A and 108B), and the semiconductor layers 106 and 108 are stacked in an alternating manner in the Z-direction. In some embodiments, the semiconductor layer 106B is form vertically between a group of semiconductor layers 108A and a group of semiconductor layers 108B. In some embodiments, a thickness of the semiconductor layer 106B is greater than the thickness of the semiconductor layers 106A, as shown in FIG. 1.

The semiconductor layers 108 may include a semiconductor material, such as silicon, germanium, silicon carbide, silicon phosphide, gallium arsenide, gallium phosphide, indium phosphide, indium arsenide, and/or indium antimonide, SiGe, SiPC, GaAsP, AlInAs, AlGaAs, GaInAs, GaInP, and/or GaInAsP. In some embodiments, the semiconductor layers 108A include SiGe for p-type transistors, and the semiconductor layers 108B include Si for n-type transistors. Alternatively, the semiconductor layers 108A include Si for n-type transistors, and the semiconductor layers 108B include SiGe for p-type transistors. In some embodiments, the semiconductor layers 108 are all made of silicon, and the type of the transistors depend on a work function metal layer wrapped around the nanostructures that are formed from the semiconductor layers 108.

The semiconductor layers 106 and 108 may have different semiconductor compositions. In some embodiments, semiconductor layers 106 are formed of SiGe and the semiconductor layers 108 are formed of Si. In these embodiments, the additional germanium content in the semiconductor layers 106 allow selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over or on the substrate 102 using an epitaxial growth such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 106 and 108 are grown alternatingly, one-after-another, to form the stack 103.

In some embodiments, the two semiconductor layers 108A are used for the PFET of the CFET, and the two semiconductor layers 108B are used for the NFET of the CFET. In these embodiments, in the CFET, the NFET is disposed over the PFET. In other embodiments, the two semiconductor layers 108A are used for the NFET of the CFET, and the two semiconductor layers 108B are used for the PFET of the CFET. In these embodiments, in the CFET, the PFET is disposed over the NFET. It is noted that, four layers of the semiconductor layers 106 and four layers of the semiconductor layers 108 are alternately and vertically arranged (or stacked) as shown in FIG. 1, which are for illustrative purposes only and not intended to be limiting beyond what is specifically recited in the claims. The number of the semiconductor layers depends on the desired number of channel members for the semiconductor device. For example, the number of layers of the semiconductor layers 108A may be 1, 2, 3, 4, or more, and the number of layers of the semiconductor layers 108B may be 1, 2, 3, 4, or more.

Referring to FIG. 2, the substrate 102 and the stack 103 are patterned to form fin structures 112 (including fin structures 112A and 112B) over the substrate 102, in accordance with some embodiments. For patterning purposes, the stack 103 may include a hard mask layer 110 over the topmost semiconductor layer. The hard mask layer 110 may be a single layer or multi-layer structure.

In some embodiments, each of the fin structures 112 includes a base fin (i.e., base portions 102A and 102B) formed from the substrate 102, and a stack portion formed from the stack 103 over the base fin, as shown in FIG. 2. The stack portion of each of the fin structures 112 includes the semiconductor layers 106 and 108 that are alternately stacked in the Z-direction. In some embodiments, the fin structures 112A and 112B extend in the X-direction, and are arranged in the Y-direction.

The fin structures 112 may be patterned using suitable processes including double-patterning or multi-patterning processes. For example, in some embodiments, a material layer is formed over the stack 103 and patterned using a lithography process. Spacers are formed alongside the patterned material layer using a self-aligned process. The material layer is then removed, and the remaining spacers, or mandrels, may then be used to pattern the fin structures 112 by etching the stack 103 and the substrate 102. The etching process may include dry etching, wet etching, reactive ion etching (RIE), and/or other suitable processes. In some embodiments, the lithography processes include photoresist coating (e.g., spin-on coating), soft baking, mask aligning, exposure, post-exposure baking, developing the photoresist, rinsing, and drying (e.g., hard baking). In other embodiments, the lithography processes may be implemented or replaced by other suitable methods, such as maskless photolithography, electron-beam (e-beam) writing, and ion-beam writing.

Still referring to FIG. 2, isolation structures 104 are formed over the substrate 102, in accordance with some embodiments. In some embodiments, the isolation structures 104 extend in the X-direction and are arranged with the fin structures 112 in the Y-direction. In other words, the isolation structures 104 are formed on opposite sides of the fin structures 112 in the Y-direction. In some embodiments, the isolation structures 104 are formed around the fin structures 112. In some embodiments, the top surfaces of the isolation structures 104 are lower than the top surfaces of the substrate 102 (more specifically, top surfaces of the base portions 102A and 102B).

The isolation structures 104 may include different structures, such as shallow trench isolation (STI) structures, deep trench isolation (DTI) structures, and/or local oxidation of silicon (LOCOS) structures. In some embodiments, a dielectric material for the isolation structures 104 is first deposited over the workpiece 100. The dielectric material may include silicon oxide (SiO₂), silicon nitride (Si₃N₄), silicon oxynitride (SiON), fluoride-doped silica glass (FSG), low-k dielectrics, other suitable materials, or combinations thereof. Exemplary low-k dielectric materials include carbon doped silicon oxide, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other low-k dielectric materials, or combinations thereof.

The dielectric material may be deposited using a deposition process, such as CVD, subatmospheric CVD (SACVD), flowable CVD (FCVD), ALD, spin-on coating, or other suitable process. The deposited dielectric material is then thinned and planarized, for example by a chemical mechanical polishing (CMP) process. The planarized dielectric material is further recessed by a dry etching process, a wet etching process, and/or a combination thereof to form the isolation structures 104. In some embodiments, the stack portions of the fin structures 112 rise above the isolation structures 104 while the base portions 102A and 102B are surrounded by the isolation structures 104, as shown in FIG. 2.

Referring to FIGS. 3A and 3B, the hard mask layer 110 is removed and a dummy gate structure 114 is formed over the fin structures 112 and the isolation structures 104, in accordance with some embodiments. The dummy gate structure 114 may be configured to extend along the Y-direction and wrap around top surfaces and side surfaces of the fin structures 112. In some embodiments, to form the dummy gate structure 114, a dummy gate dielectric material for a dummy gate dielectric layer 116 is first formed over fin structures 112 and over the isolation structures 104. In some embodiments, the dummy gate dielectric material may include, for example, a dielectric material such as a nitride (e.g., Si₃N₄, SiON), a carbide (e.g., silicon carbide (SiC)), an oxide (e.g., SiO₂), or other suitable materials.

Then, in some embodiments, a dummy gate electrode material for a dummy gate electrode 118 is formed over the dummy gate dielectric material. The dummy gate electrode material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by a thermal oxidation process and/or a deposition process (e.g., physical vapor deposition (PVD), CVD, PECVD, and ALD).

After the formation of the dummy gate electrode material and the dummy gate dielectric material, lithography and etching processes may be performed to remove portions of the dummy gate electrode material and the dummy gate dielectric material, thereby forming the dummy gate structure 114 having the dummy gate electrode 118 and the dummy gate dielectric layer 116. The dummy gate structure 114 may undergo a gate replacement process through subsequent processing to form metal gates, such as a high-k metal gate, as discussed in greater detail below.

Referring to FIGS. 4A and 4B, gate spacers 120 are formed on sidewalls of the dummy gate structure 114, and over top surfaces and on sidewalls of the fin structures 112, in accordance with some embodiments. In some embodiments, the gate spacers 120 are formed on opposite sidewalls of the fin structures 112, and formed on opposite sidewalls of the dummy gate structures 114, as shown in FIGS. 4A and 4B.

The gate spacers 120 may include multiple dielectric materials and be selected from a group consisting of Si₃N₄, SiO₂, SiC, silicon oxycarbide (SiOC), SiON, silicon oxycarbon nitride (SiOCN), carbon doped oxide, nitrogen doped oxide, porous oxide, air gap, or a combination thereof. In some embodiments, the gate spacers 120 include a low-k dielectric material, such as those described herein. In some embodiments, the gate spacers 120 may include a single layer or a multi-layer structure.

In some embodiments, the gate spacers 120 may be formed by conformally depositing a spacer layer of dielectric material over the isolation structures 104, the fin structures 112, and the dummy gate structure 114, followed by an anisotropic etching process to remove top portions of the spacer layer from the top surfaces of the isolation structures 104, the fin structures 112, and the dummy gate structure 114. After the anisotropic etching process, portions of the spacer layer on the sidewalls of the fin structures 112 and the dummy gate structure 114 substantially remain and become the gate spacers 120. In some embodiments, the anisotropic etching process is a dry (e.g., plasma) etching process. Alternatively, the formation of the gate spacers 120 may involve chemical oxidation, thermal oxidation, CVD, PVD, ALD, high-density plasma CVD (HDPCVD), MOCVD, RPCVD, PECVD, LPCVD, atomic layer CVD (ALCVD), atmospheric pressure CVD (APCVD), FCVD, and/or other suitable methods.

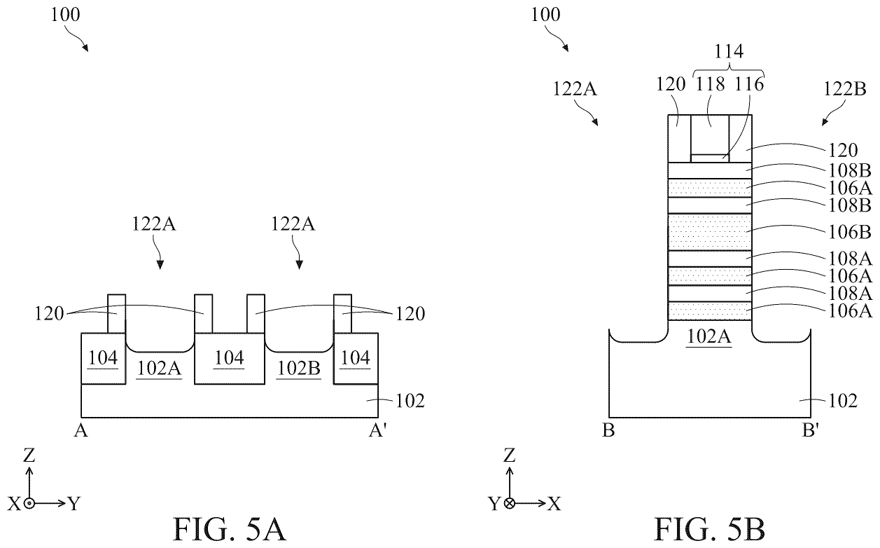

Referring to FIGS. 5A and 5B, the fin structures 112 are recessed to form source/drain trenches 122 in the fin structures 112, in accordance with some embodiments. In some embodiments, in each of the fin structures 112A and 112B, the source/drain trenches 122 include a source/drain trench 122A and a source/drain trench 122B that are on opposite sides of the dummy gate structure 114 in the X-direction.

In some embodiments, the source/drain trenches 122 are formed by performing one or more etching processes to remove portions of the semiconductor layers 106 and 108 and the substrate 102 that do not vertically overlap or be covered by the dummy gate structure 114 and the gate spacers 120. In some embodiments, the etching process may be performed by using a single etchant or multiple etchants. In some embodiments, portions of the substrate 102 are etched, so that the source/drain trenches 122 extend into the substrate 102 and each has a concave surface, as shown in FIGS. 5A and 5B. In some embodiments, portions of the gate spacers 120 on opposite sidewalls of the fin structures 112 in the Y-direction are removed, as shown in FIG. 5A. In these embodiments, the height of the gate spacers 120 on the opposite sidewalls of the fin structures 112 in the Y-direction are reduced.

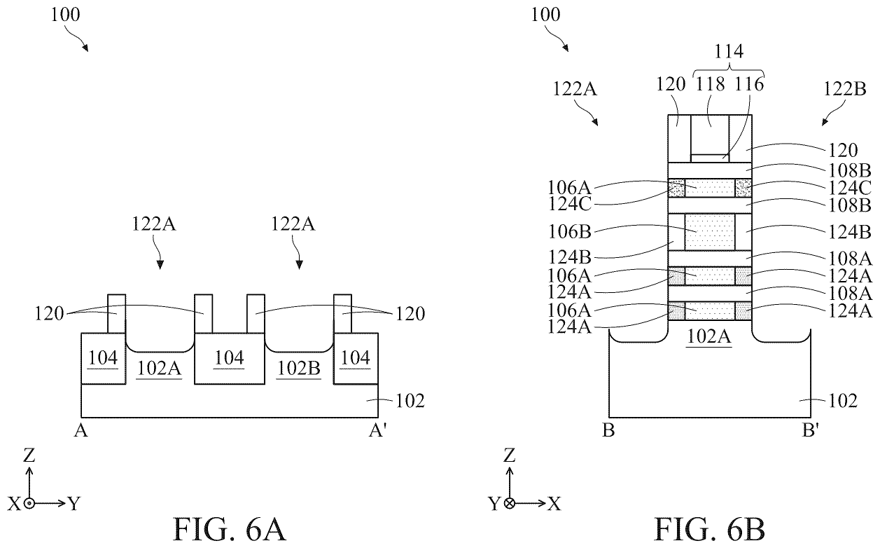

Referring to FIGS. 6A and 6B, the inner spacers 124 are formed between the semiconductor layers 108 as well as between the semiconductor layer 108 and the substrate 102, in accordance with some embodiments. More specifically, the inner spacers 124 include inner spacers 124A, 124B, and 124C. The inner spacers 124A may be formed between the semiconductor layers 108A and between the semiconductor layer 108A and the substrate 102. The inner spacers 124B may be vertically sandwiched between the inner spacers 124A and 124B, and between the topmost semiconductor layer 108A and the bottommost semiconductor layer 108B. The inner spacers 124C may be formed between the semiconductor layers 108B.

In some embodiments, the semiconductor layers 106A and 106B exposed in the source/drain trenches 122 are partially recessed through a selective etching process, and the semiconductor layers 108 are not etched. More specifically, the selective etching process is performed that selectively etches the side portions of the semiconductor layers 106 below the gate spacers 120 through the source/drain trenches 122, with minimal etching (or substantially no etching) of the semiconductor layers 108 and the substrate 102. After the selective etching process, inner spacer recesses are vertically formed between the semiconductor layers 108 as well as between the semiconductor layers 108 and the substrate 102, below the gate spacers 120. The selective etching process is configured to laterally etch (e.g., in the X-direction) the semiconductor layers 106 below the gate spacers 120. The selective etching process may be a dry etching process, a wet etching process, other suitable etching process, or a combination thereof.

Next, in some embodiments, a deposition process is performed to conformally form a spacer layer into the source/drain trenches 122 and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially or completely fills the source/drain trenches 122 and fully fills the inner spacer recesses. The deposition process is configured to ensure that the spacer layer fills the inner spacer recesses.

The spacer layer may include a material that is different than the materials of the semiconductor layers 108 and the gate spacers 120 to achieve desired etching selectivity. In some embodiments, the spacer layer include one or more dielectric material that includes silicon, oxygen, carbon, nitrogen, other suitable material, or combinations thereof (e.g., SiO₂, SION, SiOC, SiCN, SiOCN). In some embodiments, the spacer layer include a low-k dielectric material, such as those described herein. In some embodiments, the spacer layer includes a dielectric material having higher k value (dielectric constant) than the gate spacers 120.

Then, in some embodiments, the inner spacers 124 are formed to fill the inner spacer recesses between the semiconductor layers 108 as well as between the semiconductor layer 108 and the substrate 102. More specifically, an etching process is performed to selectively etch the spacer layer to form the inner spacers 124 with minimal etching (or substantially no etching) of the semiconductor layers 108, the substrate 102, the dummy gate structure 114, and the gate spacers 120. The etching process may be an anisotropic etching process, such that portions of the spacer layer that do not vertically overlap or be covered by the dummy gate structure 114 and the gate spacers 120 are removed.

In some embodiments, sidewalls of the inner spacers 124 are aligned to the sidewalls of the gate spacers 120 and the semiconductor layers 108. Therefore, the inner spacers 124 are formed on opposite sides of the dummy gate structure 114. In some embodiments, the thickness of the gate spacers 120 is greater than the thickness of the inner spacers 124 in the X-direction for capacitance reduction between source/drain contacts and the gate structure. In some embodiments, the gate spacers 120 has lower k value than the inner spacers 124 to reduce the capacitance further.

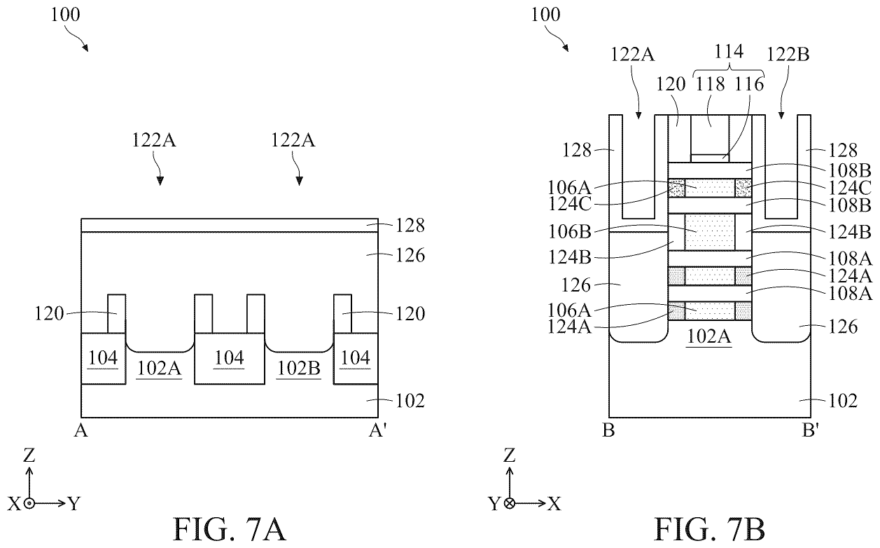

Referring to FIGS. 7A and 7B, polymer layers 126 and cover spacers 128 are formed in the source/drain trenches 122, in accordance with some embodiments. More specifically, the polymer layers 126 are first formed in lower parts of the source/drain trenches 122 to cover the top surfaces of the substrate 102, the sidewalls of the inner spacers 124A and the semiconductor layers 108A, and the sidewalls of first portions of the inner spacers 124B (e.g., lower portions of the inner spacers 124B) exposed in the source/drain trenches 122. In some embodiments, top surfaces of the polymer layers 126 are lower than the semiconductor layers 108B, such that second portions of the inner spacers 124B (e.g., upper portions of the inner spacers 124B) are still exposed in the source/drain trenches 122. In some embodiments, the polymer layers 126 are also formed on the gate spacers 120 and the isolation structures 104, as shown in FIG. 7A.

After forming the polymer layers 126, the cover spacers 128 are conformally formed over the polymer layers 126 and on the sidewalls of the semiconductor layers 108B, the gate spacers 120, the inner spacers 124C, and the second portions of the inner spacers 124B (e.g., upper portions of the inner spacers 124B). The polymer layers 126 may be formed of fluorine-containing polymer and its molecular structure includes silicon (Si), carbon (C), nitrogen (N), or fluorine (F). In some embodiments, the polymer layers 126 include fluorinated silicone or fluorinated polysilane. In some embodiments, the polymer layers 126 are spin-on-carbon layers. The polymer layers 126 may be deposited using CVD, FCVD, or spin-on coating. The cover spacers 128 may include aluminum oxide (Al₂O₃).

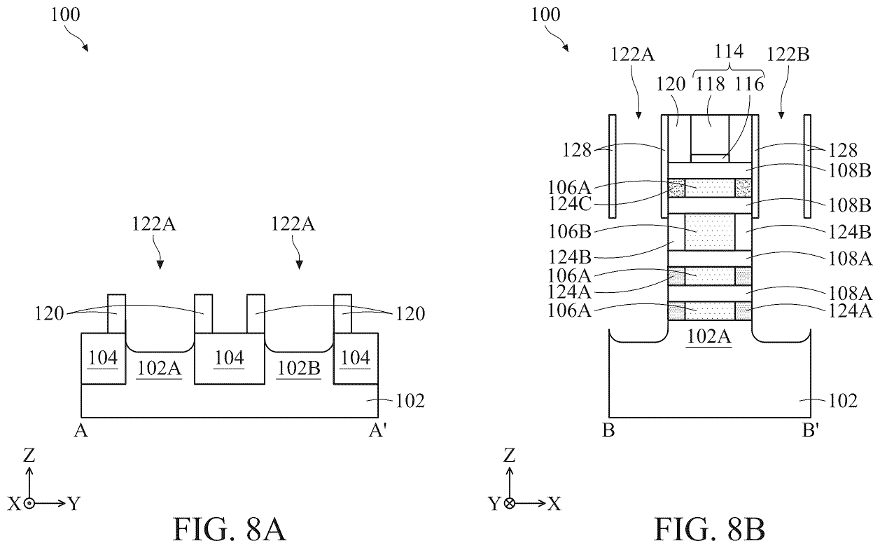

Referring to FIGS. 8A and 8B, the polymer layers 126 and horizontal portions of the cover spacers 128 are removed, in accordance with some embodiments. More specifically, an anisotropic etching process is performed to remove the horizontal portions of the cover spacers 128 to exposed top surfaces of the polymer layers 126, and then a selective etching process is performed to remove the polymer layers 126. The selective etching process is performed that selectively etches the polymer layers 126 below the cover spacers 128 through the source/drain trenches 122, with minimal etching (or substantially no etching) of the semiconductor layers 108A, the substrate 102, and the inner spacers 124. The selective etching process is a dry etching process, a wet etching process, other suitable etching process, or combinations thereof.

In some embodiments, vertical portions of the cover spacers 128 are partially removed or trimmed, but the remained vertical portions of the cover spacers 128 still cover the sidewalls of the gate spacers 120, the semiconductor layers 108B, the inner spacers 124C, and the second portions of the inner spacers 124B, and expose the sidewalls of the first portions of the inner spacers 124B (e.g., lower portions of the inner spacers 124B), such that the first portions of the inner spacers 124B are exposed in the source/drain trenches 122, as shown in FIG. 8B.

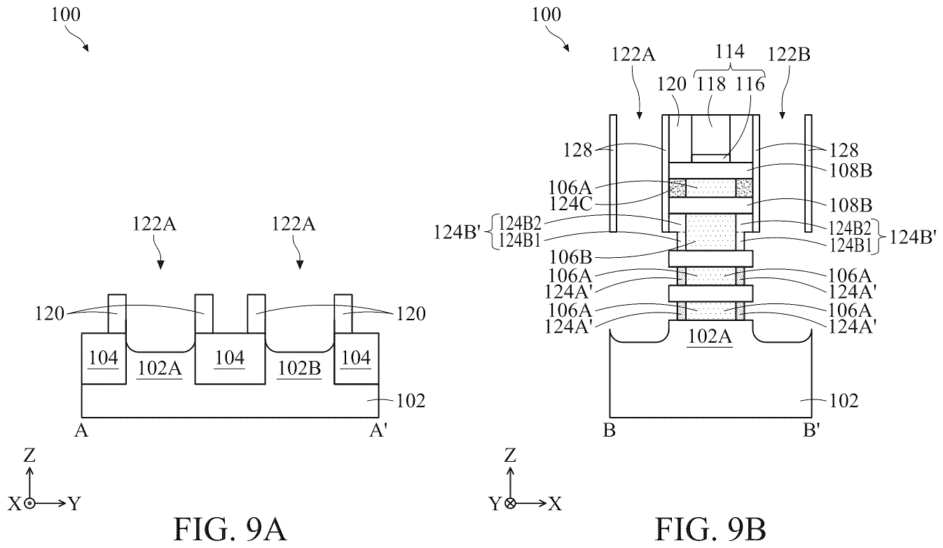

Referring to FIGS. 9A and 9B, the inner spacers 124A and the first portions of the inner spacers 124B are partially recesses, in accordance with some embodiments. In some embodiments, the inner spacers 124A and the first portions of the inner spacers 124B exposed in the source/drain trenches 122 are partially recessed through a selective etching process, and the inner spacers 124C and the second portions of the inner spacers 124B covered by the cover spacers 128 are not etched. More specifically, the selective etching process is performed that selectively etches the side portions of the inner spacers 124A and the first portions of the inner spacers 124B exposed in the source/drain trenches 122, with minimal etching (or substantially no etching) of the semiconductor layers 108, the substrate 102, and the cover spacers 128. The selective etching process may be a dry etching process, a wet etching process, other suitable etching process, or a combination thereof.

After the selective etching process, the inner spacers 124A are partially recessed to form recessed inner spacers 124A′. Similarly, the inner spacers 124B are partially recessed to form recessed inner spacers 124B′ that each includes a recessed first portion 124B1 that is partially recessed and a second portion 124B2 that is not recessed. In some embodiments, the recessed inner spacers 124A′ are vertically between the semiconductor layers 108A as well as between the semiconductor layer 108A and the substrate 102. In some embodiments, the recessed inner spacers 124B′ are between the topmost semiconductor layer 108A and the bottommost semiconductor layer 108B, wherein the recessed first portions 124B1 are in contact with the topmost semiconductor layer 108A, and the second portions 124B2 are in contact with the bottommost semiconductor layer 108B, as shown FIG. 9B.

In some embodiments, in the X-direction, the horizontal dimensions of the recessed inner spacers 124A′ and the recessed first portions 124B1 of the recessed inner spacers 124B′ are less than the horizontal dimensions of the inner spacers 124C and the second portions 124B2 of the recessed inner spacers 124B′, as shown in FIG. 9B. In further embodiments, in the X-direction, the horizontal dimensions of the gate spacers 120 are greater than the horizontal dimensions of the inner spacers 124C and the second portions 124B2. In some embodiments, the end portions of the semiconductor layers 108A protrude from the recessed inner spacers 124A′ and the recessed first portions 124B1, and are exposed in the source/drain trenches 122, as shown in FIG. 9B.

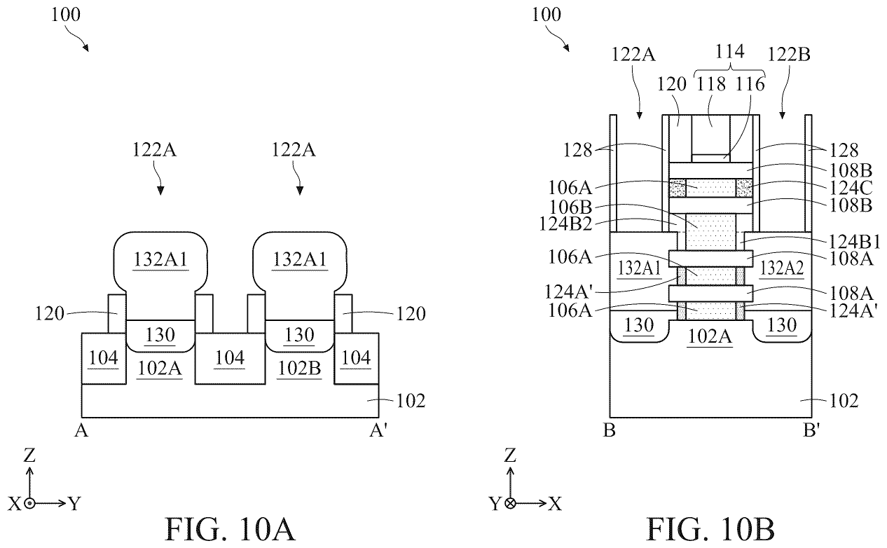

Referring to FIGS. 10A and 10B, after forming the recessed inner spacers 124A′ and 124B′, bottom isolation layers 130 and source/drain features 132A are formed in the lower parts of the source/drain trenches 122 and below the cover spacers 128, in accordance with some embodiments. In some embodiments, the bottom isolation layers 130 are formed over the substrate 102 exposed in the source/drain trenches 122 and the source/drain features 132A are formed over the bottom isolation layers 130. In these embodiments, the bottom isolation layers 130 are vertically between and in contact with the source/drain features 132A and the substrate 102 in the Z-direction, and on opposite sides of the dummy gate structure 114 in the X-direction.

In some embodiments, the top surfaces of the bottom isolation layers 130 are higher than the topmost surfaces of the substrate 102 (i.e., the top surfaces of the base portions 102A and 102B) to ensure that the bottom isolation layers 130 separate the source/drain features 132A from the substrate 102. In some embodiments, each of the bottom isolation layers 130 includes a protruding portion extending in the X-direction. The protruding portion is in contact with an exposed portion of the top surface of the base portion (i.e., base portions 102A and 102B), wherein the exposed portion is generated due to the formation of the recessed inner spacers 124A′, as shown in FIG. 10B. The protruding portion is also in contact with the recessed inner spacers 124A′. In some embodiments, the dielectric material of the bottom isolation layers 130 may include Si₃N₄, SiO₂, SiC, SiOC, SiON, SiCN, SiOCN, high-k dielectrics, other suitable materials, or combinations thereof. In some embodiments, the bottom isolation layers 130 may be deposited by CVD, PVD, ALD, HDPCVD, MOCVD, RPCVD, PECVD, LPCVD, ALCVD, APCVD, other suitable methods, or combinations thereof.

In some embodiments, the source/drain features 132A include source/drain features 132A1 and 132A2 that are formed on opposite sides of the dummy gate structure 114, and in the source/drain trenches 122A and 122B respectively, as shown in FIG. 10B. In some embodiments, the source/drain features 132A are connected to and in contact with the semiconductor layers 108A. In other words, the source/drain features 132A are attached to opposite sides of the semiconductor layers 108A. In some embodiments, the semiconductor layers 108A connect the source/drain feature 132A1 to the source/drain feature 132A2. In some embodiments, the source/drain features 132A are in contact with the recessed inner spacers 124A′ and the recessed first portions 124B1 of the recessed inner spacers 124B′. In further embodiments, the source/drain features 132A are in contact with bottom surfaces of the second portions 124B2 of the recessed inner spacers 124B′, wherein the bottom surfaces of the second portions 124B2 are generated due to the formation of the recessed first portion 124B1. In some embodiments, since the end portions of the semiconductor layers 108A protrude from the recessed inner spacers 124A′ and the recessed first portions 124B1, the end portions of the semiconductor layers 108A are surrounded by the source/drain features 132A.

In some embodiments, the source/drain features 132A are formed by epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the source/drain features 132A are grown from the semiconductor layers 108A rather than the semiconductor layers 108B, the bottom isolation layers 130, and the substrate 102, it is because that the cover spacers 128 cover the sidewalls of the semiconductor layers 108B, and the bottom isolation layers 130 cover the surface of the substrate 102. In other embodiments, the bottom isolation layers 130 are omitted, such that the source/drain features 132A are grown from the semiconductor layers 108A and the substrate 102.

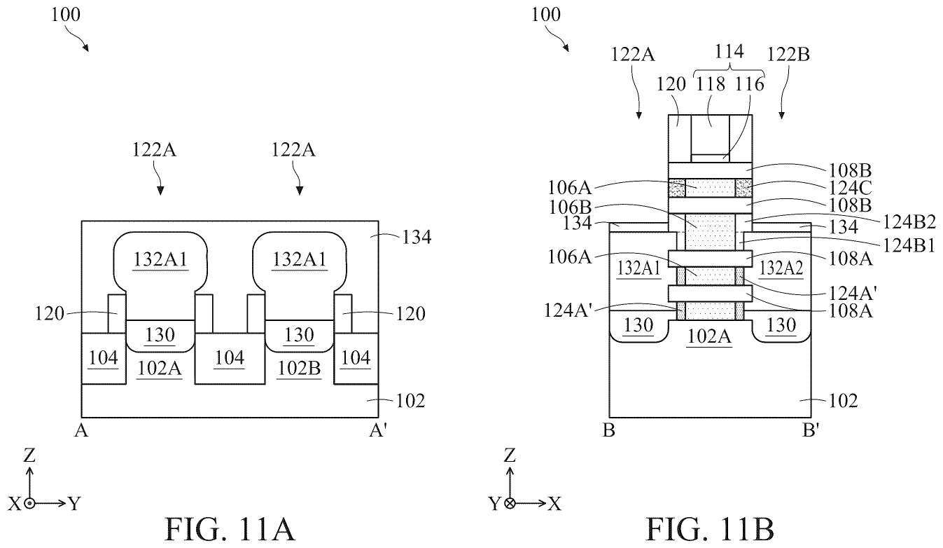

Referring to FIGS. 11A and 11B, the cover spacers 128 are removed through a selective etching process, and then an interlayer dielectric (ILD) layer 134 is formed in the source/drain trenches 122, in accordance with some embodiments. In some embodiments, the selective etching process is performed that selectively etches the cover spacers 128 through the source/drain trenches 122, with minimal etching (or substantially no etching) of the semiconductor layers 108B, the gate spacers 120, and the inner spacers 124. The selective etching process may be a dry etching process, a wet etching process, other suitable etching process, or combinations thereof.

After removing the cover spacers 128, the ILD layer 134 is then formed over the substrate 102, the isolation structures 104, and the source/drain features 132A and between the spaces between the source/drain features 132A. In some embodiments, the ILD layer 134 may be formed by CVD, PVD, ALD, HDPCVD, MOCVD, RPCVD, PECVD, LPCVD, ALCVD, APCVD, FCVD, or other suitable methods. Then, the ILD layer 134 over the source/drain features 132A are recessed by performing one or more lithography and etching processes, so that the sidewalls of the semiconductor layers 108B, the inner spacers 124C, and the second portions 124B2 of the recessed inner spacers 124B′ over the source/drain features 132A are exposed.

In some embodiments, the ILD layer 134 may include tetraethylorthosilicate (TEOS) formed oxide, un-doped silicate glass, or doped silicon oxide such as borophosphosilicate glass (BPSG), FSG, phosphosilicate glass (PSG), boron silicate glass (BSG), low-k dielectric materials such as those described herein, other suitable dielectric materials, or combinations thereof.

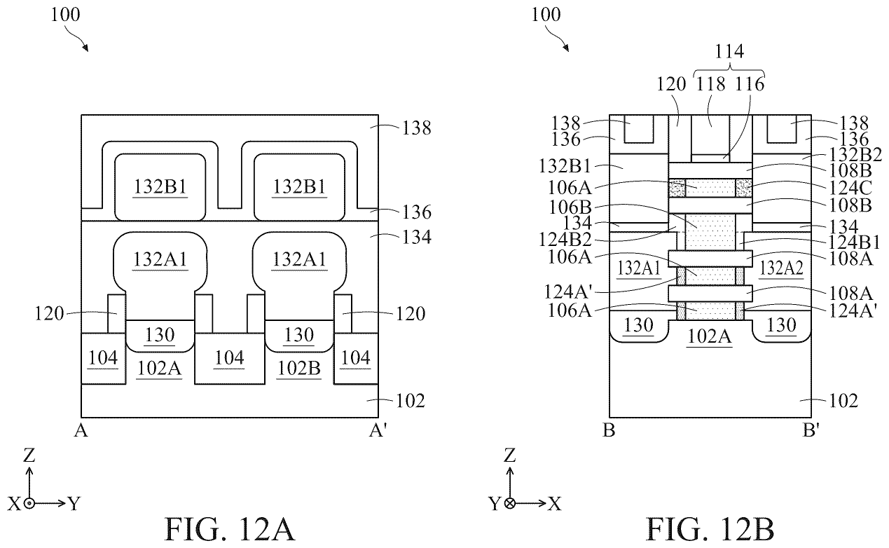

Referring to FIGS. 12A and 12B, the source/drain features 132B are formed in the source/drain trenches 122, in accordance with some embodiments. In some embodiments, the source/drain features 132B are formed over the ILD layer 134 in the source/drain trenches 122. In some embodiments, the source/drain features 132B include source/drain features 132B1 and 132B2 that are formed on opposite sides of the dummy gate structure 114, and over the source/drain features 132A1 and 132A2 respectively, as shown in FIG. 12B. In other words, the source/drain features 132B1 and 132B2 vertically overlaps the source/drain features 132A1 and 132A2, respectively.

In some embodiments, the source/drain features 132B are connected to and in contact with the semiconductor layers 108B. In other words, the source/drain features 132B are attached to opposite sides of the semiconductor layers 108B. In some embodiments, the semiconductor layers 108B connect the source/drain feature 132B1 to the source/drain feature 132B2. In some embodiments, the source/drain features 132B are in contact with the inner spacers 124C and the second portion 124B2 of the recessed inner spacers 124B′ that are not recessed. In some embodiments, the source/drain features 132B may have top surfaces that extend higher than top surfaces of the topmost semiconductor layers 108B (e.g., in the Z-direction). In other embodiments, the top surfaces of the source/drain features 132B are substantially level with the top surfaces of the topmost semiconductor layers 108B.

In some embodiments, the source/drain features 132B may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. The source/drain features 132B are grown from the semiconductor layers 108B.

In some embodiments, the source/drain features 132A and 132B are used for the PFETs and NFETs of the CFETs, respectively, and may be referred to as p-type and n-type source/drain features, respectively. In other embodiments, the source/drain features 132A and 132B are used for the NFETs and PFETs of the CFETs, respectively, and may be referred to as n-type and p-type source/drain features, respectively.

The p-type source/drain features may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the p-type source/drain features may be doped with p-type dopants and have a doping concentration in a range from about 1×10¹⁹/cm³ to 6×10²⁰/cm³. The n-type source/drain features may include epitaxially-grown material selected from a group consisting of SiP, SiC, SiPC, SiAs, Si, or a combination thereof. In some embodiments, the epitaxially-grown material of the n-type source/drain features may be doped with n-type dopants and have a doping concentration in a range from about 2×10¹⁹/cm³ to 3×10²¹/cm³. The source/drain features 132A and 132B may be doped in-situ or ex-situ. One or more annealing processes may be performed to activate the dopants in the source/drain features 132A and 132B. The annealing processes may include rapid thermal annealing (RTA) and/or laser annealing processes.

Still referring to FIGS. 12A and 12B, contact etch stop layers (CESLs) 136 are formed over the source/drain features 132B and the ILD layer 134, and an ILD layer 138 is formed over the CESLs 136 to fill the spaces between the source/drain features 132B, in accordance with some embodiments. In some embodiments, the CESLs 136 are conformally formed on sidewalls of the gate spacers 120, and on the top surfaces and the sidewalls of the source/drain features 132B. In some embodiments, the CESLs 136 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESLs 136 may be formed by CVD, PVD, ALD, HDPCVD, MOCVD, RPCVD, PECVD, LPCVD, ALCVD, APCVD, FCVD, or other suitable methods.

The ILD layer 138 is formed over and between the CESLs 136 to fill the space between the CESLs 136 and in the source/drain trenches 122. In some embodiments, the ILD layer 138 includes a material that is different than the CESLs 136. In some embodiments, the ILD layer 138 may include TEOS formed oxide, un-doped silicate glass, or doped silicon oxide such as BPSG, FSG, PSG, BSG, low-k dielectric materials, other suitable dielectric materials, or combinations thereof. The ILD layer 138 may be formed by CVD, PVD, ALD, HDPCVD, MOCVD, RPCVD, PECVD, LPCVD, ALCVD, APCVD, FCVD, or other suitable methods. After forming the CESLs 136 and the ILD layer 138, a CMP process is performed to reduce heights of the CESLs 136 and the ILD layer 138 until top surface of the dummy gate electrode 118 is exposed.

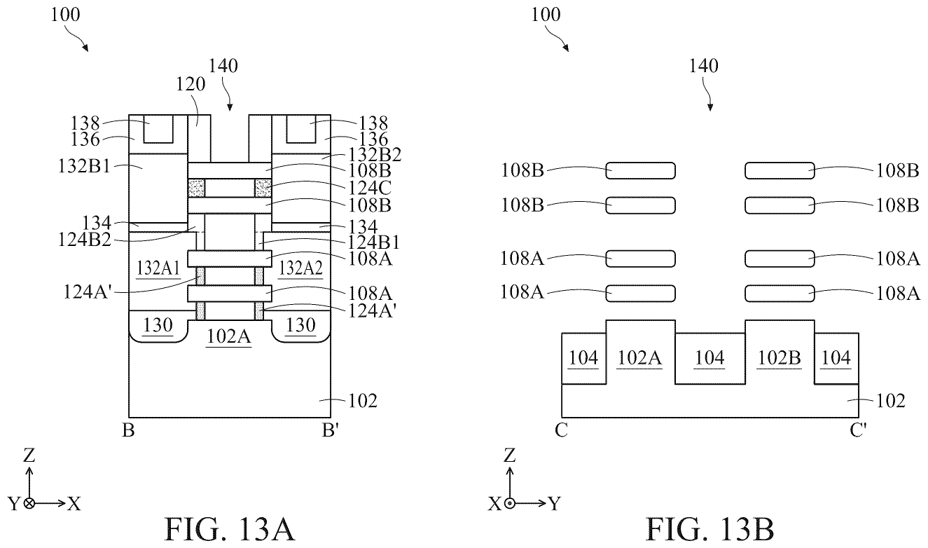

Referring to FIGS. 13A and 13B, the dummy gate structure 114 are selectively removed through any suitable lithography and etching processes, in accordance with some embodiments. In some embodiments, the lithography process may include forming a photoresist layer (resist), exposing the resist to a pattern, performing a post-exposure bake process, and developing the resist to form a masking element, which exposes a region including the dummy gate structure 114. Then, the dummy gate structure 114 is selectively etched through the masking element. The gate spacers 120 may be used as the masking element or a part thereof. Etch selectivity may be achieved by selecting appropriate etching chemicals, and the dummy gate structure 114 may be removed without substantially affecting the CESLs 136 and the ILD layer 138. The removal of the dummy gate structure 114 creates a gate trench 140 that exposes the top surfaces of the topmost semiconductor layers.

Still referring to FIGS. 13A and 13B, the semiconductor layers 106 are selectively removed through the gate trench 140, using a wet or dry etching process for example, in accordance with some embodiments. After the semiconductor layers 106 are selectively removed, the semiconductor layers 108A and 108B are exposed in the gate trench 140 to form the nanostructures stacked on top of each other. As such, the semiconductor layers 108 may be referred to as nanostructures. The semiconductor layers 108A are spaced apart from each other and stacked vertically in the Z-direction, and the semiconductor layers 108B are directly over the semiconductor layers 108A and are spaced apart from each other and stacked vertically in the Z-direction. This process may be referred to as a nanowire release process, a nanosheet release process, a nanowire formation process, or a nanosheet formation process.

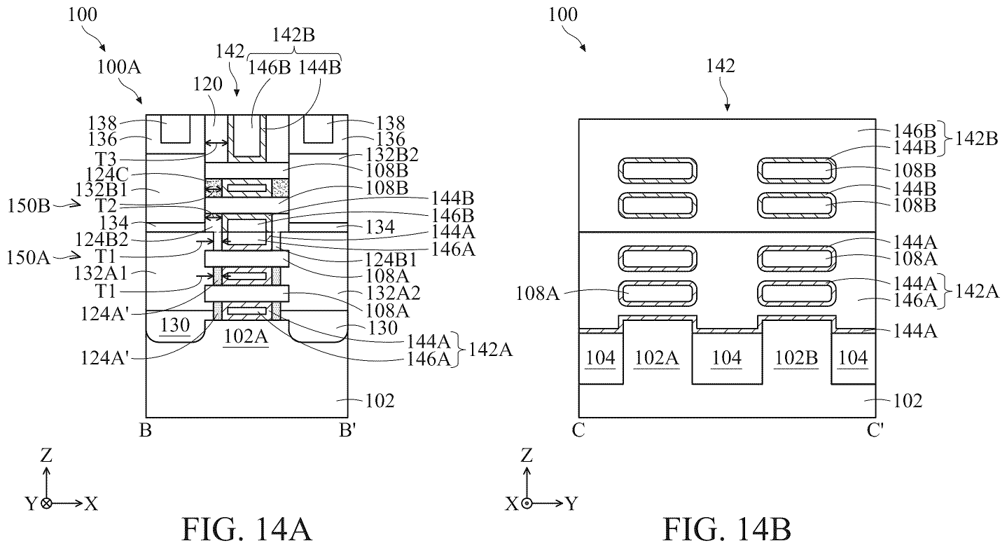

Referring to FIGS. 14A and 14B, gate structures 142 each including a gate structure 142A and a gate structure 142B are formed to replace the dummy gate structure 114, in accordance with some embodiments. In some embodiments, the gate structure 142A includes a gate dielectric layer 144A and a gate electrode layer 146A, and the gate structure 142B includes a gate dielectric layer 144B and a gate electrode layer 146B.

In some embodiments, the gate dielectric layers 144A and 144B are formed in the gate trench 140 to wrap around each of the semiconductor layers 108A and 108B, respectively. In some embodiments, the gate dielectric layers 144A and 144B are formed from the same dielectric layer, wherein the difference between the gate dielectric layers 144A and 144B is that the gate dielectric layer 144A is in contact with the gate electrode layer 146A and belongs to the lower FET of the CFET, and the gate dielectric layer 144B is in contact with the gate electrode layer 146B and belongs to the upper FET of the CFET. Then, in some embodiments, the gate electrode layer 146A is formed to wrap around the gate dielectric layers 144A and 144B and each of the semiconductor layers 108A and 108B.

Next, in some embodiments, the gate electrode layer 146A in the gate trench 140 is etched back to expose the semiconductor layers 108B. In some embodiments, portions of the gate electrode layer 146A that are wrapped around the semiconductor layers 108B are removed by one or more etching processes. The etching processes may be selective etching processes that selectively etch the gate electrode layer 146A, with minimal etching (or substantially no etching) of the gate dielectric layers 144A and 144B, the semiconductor layers 108B, the gate spacers 120, and the inner spacers 124. The selective etching process may be a dry etching process, a wet etching process, other suitable etching process, or combinations thereof. In some embodiments, after the etching processes, the top surface of the gate electrode layer 146A is lower than the bottommost surfaces of the semiconductor layers 108B.

Then, in some embodiments, the gate electrode layer 146B is formed in the gate trench 140 and over the gate dielectric layer 144A and the gate electrode layer 146A to wrap around the gate dielectric layer 144B and the semiconductor layers 108B. In some embodiments, the gate dielectric layer 144A is also formed on the sidewalls of the inner spacers 124A and the recessed first portions 124B1 of the recessed inner spacers 124B′, as well as over the top surfaces of the substrate 102 and the isolation structures 104. In some embodiments, the gate dielectric layer 144B is also formed on sidewalls of the inner spacers 124C, the second portions 124B2 of the recessed inner spacers 124B′, and the gate spacers 120.

In some embodiments, since the gate structure 142A is disposed below the topmost semiconductor layer 108B in the Z-direction, the gate structure 142A may be referred to as first inner gate structure. The gate structure 142A may be in contact with the recessed inner spacers 124A′ and the recessed first portions 124B1 of the recessed inner spacers 124B′. In some embodiments, the gate structure 142B may be divided into an outer gate structure and a second inner gate structure that are above and below the topmost semiconductor layer 108B in the Z-direction, respectively. The outer gate structure of the gate structure 142B may be in contact with the gate spacers 120, and the second inner gate structure of the gate structure 142B may be in contact with the inner spacers 124C and the second portions 124B2 of the recessed inner spacers 124B′.

In some embodiments, the recessed inner spacers 124A′ and the recessed first portions 124B1 of the recessed inner spacers 124B′ have a thickness T1 in the X-direction (horizontal dimension), and the inner spacers 124C and the second portions 124B2 of the recessed inner spacers 124B′ have a thickness T2 in the X-direction. In some embodiments, the thickness T2 is greater than the thickness T1 by about 0.5 nm to about 4 nm. In some embodiments, the gate spacers 120 have a thickness T3 that is greater than the thickness T2 by about 0.5 nm to about 4 nm in the X-direction.

In some embodiments, the gate dielectric layers 144A and 144B may include oxide with nitrogen doped dielectric material (initial layer) combined with metal content high-k dielectric material (e.g., k value >7.9). For example, the gate dielectric layers 144A and 144B may include HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃(STO), BaTiO₃(BTO), BaZrO, HfLaO, HfSiO, LaSiO, AlSiO, HfTaO, HfTiO, (Ba,Sr)TiO₃(BST), Al₂O₃, Si₃N₄, SiON, other suitable materials, or combinations thereof. The gate dielectric layers 144A and 144B may be formed by chemical oxidation, thermal oxidation, CVD, PVD, ALD, HDPCVD, MOCVD, RPCVD, PECVD, LPCVD, ALCVD, APCVD, FCVD, other suitable methods, or combinations thereof.

In some embodiments, one of the gate electrode layers 146A and 146B may include one or more p-type work function metal layers for PFET of the CFET, and the other one of the gate electrode layers 146A and 146B may include one or more n-type work function metal layers for NFET of the CFET. In other embodiments, the gate electrode layers 146A and 146B may include the same work function metal layer.

In some embodiments, the n-type and p-type work function metal layers may include a material such as such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the n-type and p-type work function metal layers may be deposited utilizing CVD, PVD, ALD, HDPCVD, MOCVD, RPCVD, PECVD, LPCVD, ALCVD, APCVD, FCVD, or the like. However, any suitable materials and processes may be utilized to form the n-type work function metal layer and the p-type work function metal layer.

In some embodiments, each of the gate electrode layers 146A and 146B may include a single layer or alternatively a multi-layer structure. In some embodiments, each of the gate electrode layers 146A and 146B may include a capping layer, a barrier layer, and a fill material (not shown). The capping layer may be formed adjacent to the gate dielectric layers 144A and 144B, and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed adjacent to the capping layer, and may be formed of a different material than the capping layer. For example, the barrier layer may be formed of one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

In some embodiments, the fill material may include a suitable conductive material, such as Al, W, and/or Cu. In some embodiments, the capping layer, the barrier layer, and the fill material may be deposited using a deposition process such as CVD, PVD, ALD, HDPCVD, MOCVD, RPCVD, PECVD, LPCVD, ALCVD, APCVD, FCVD, or the like, although any suitable deposition process may be used.

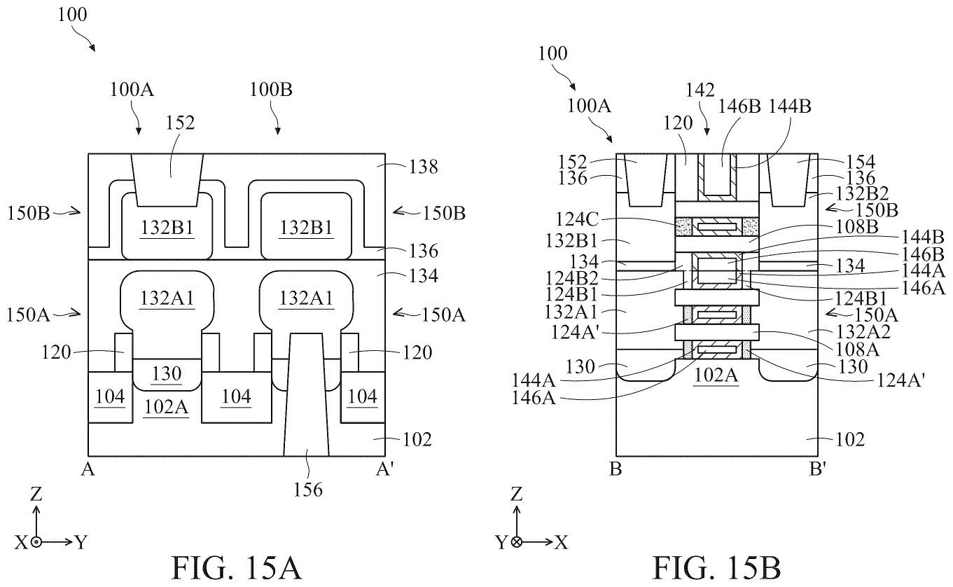

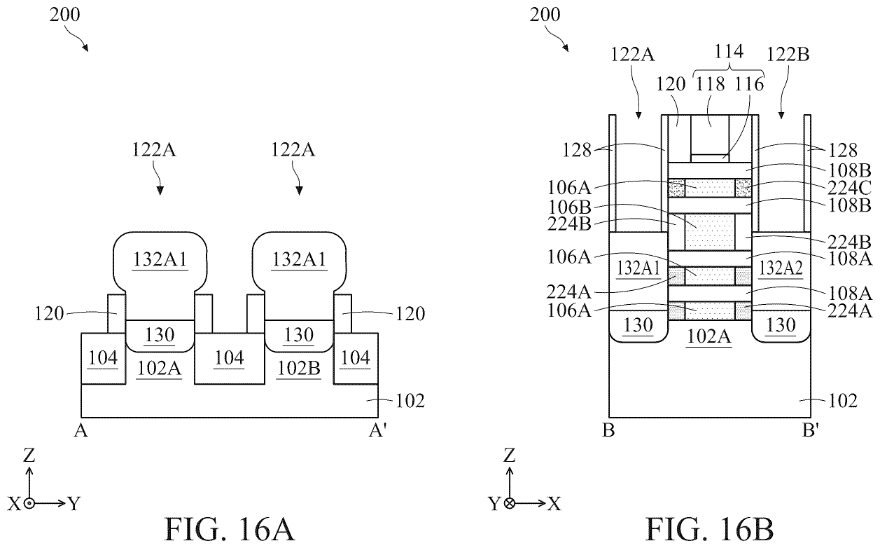

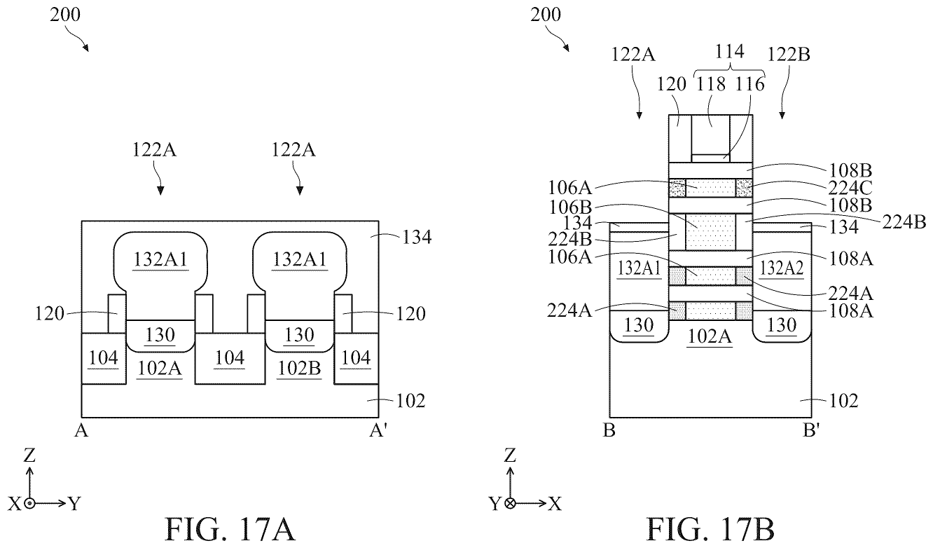

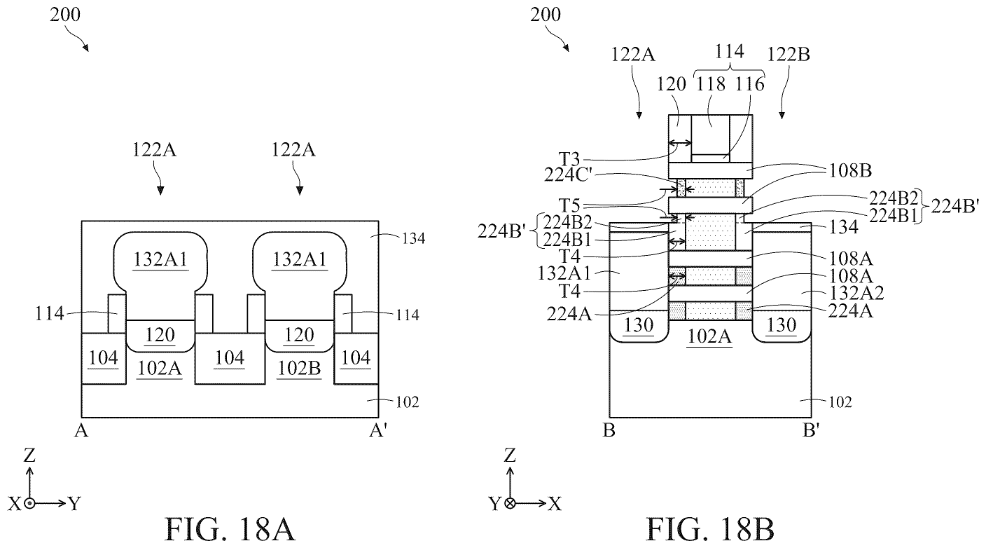

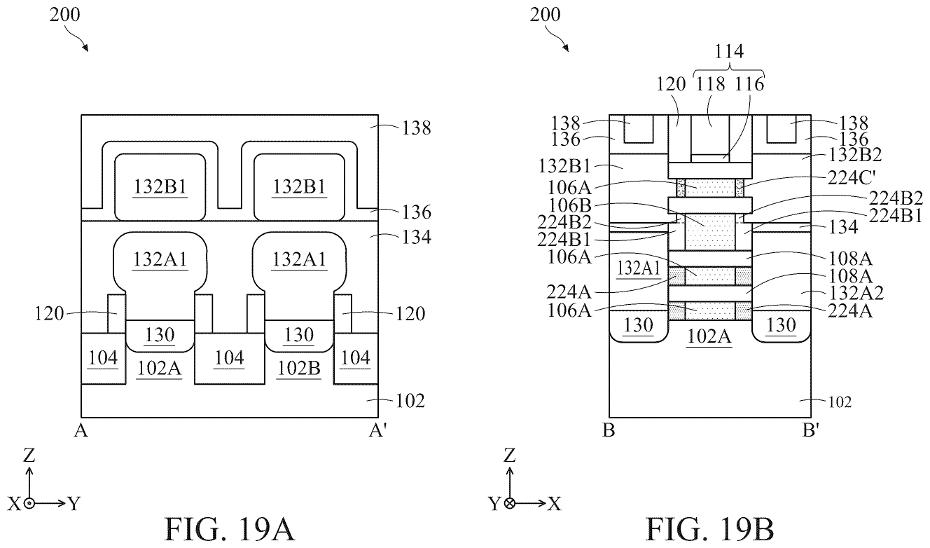

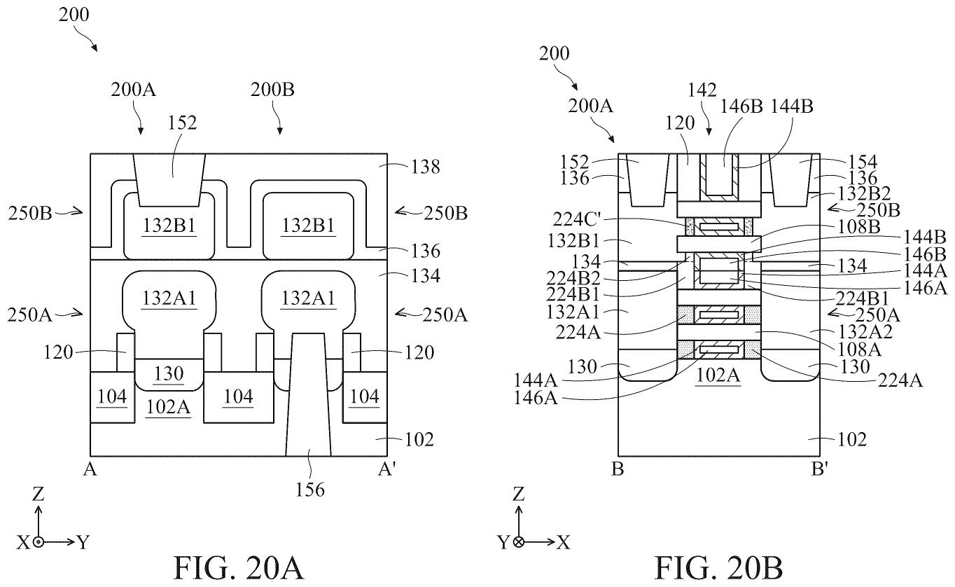

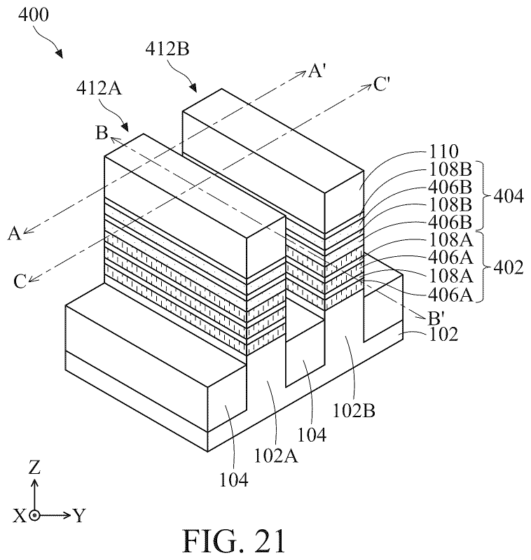

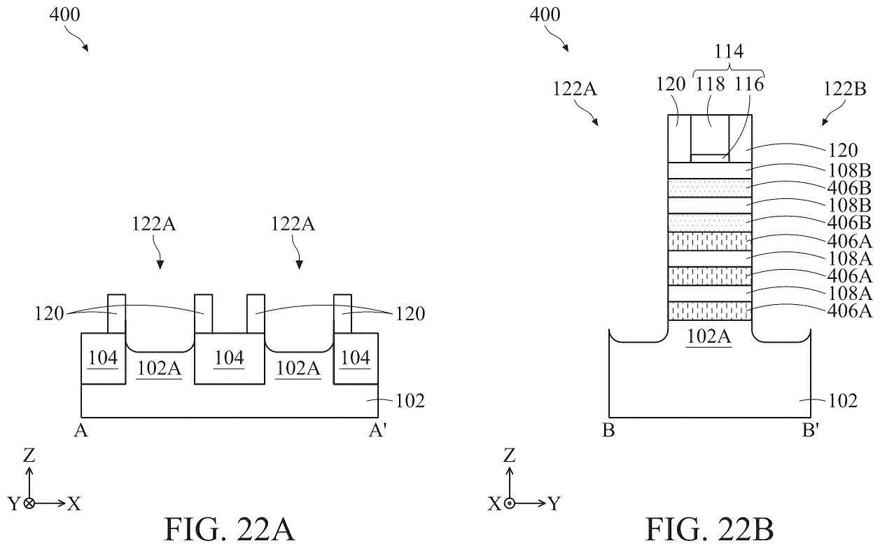

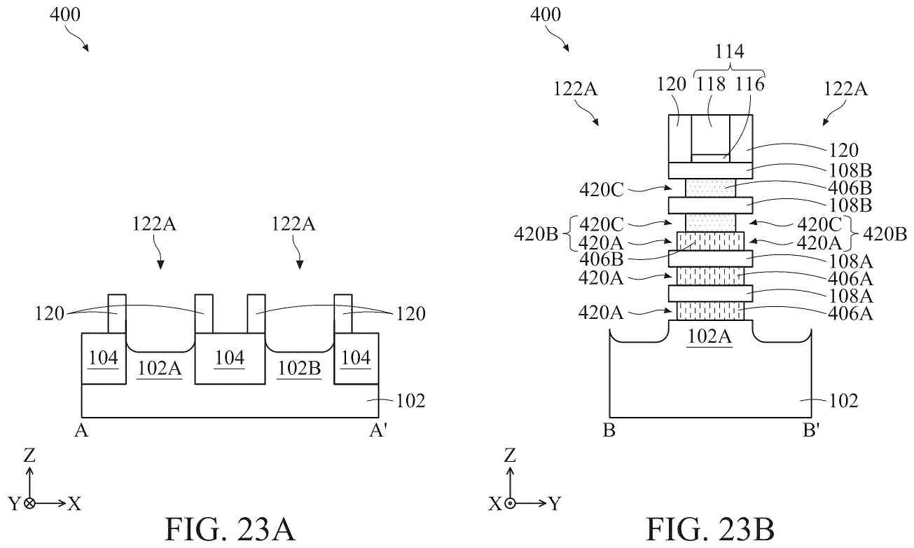

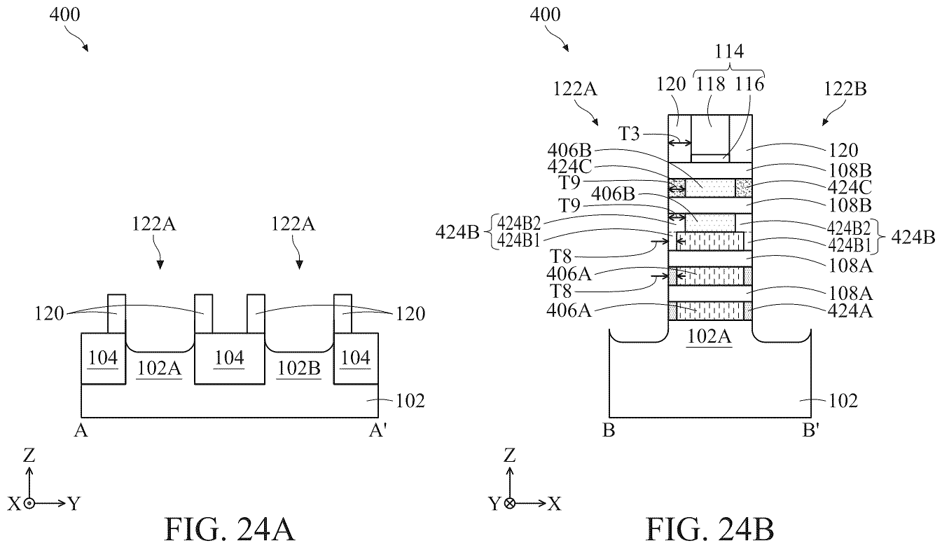

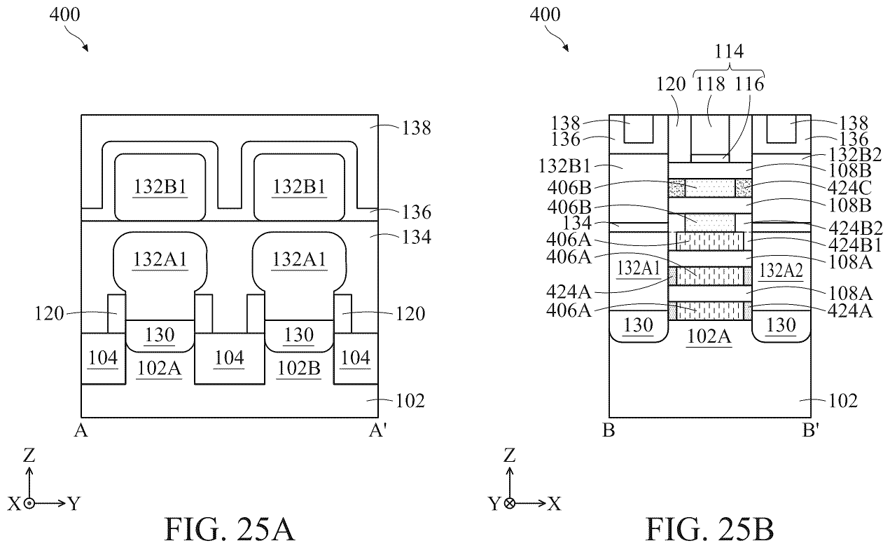

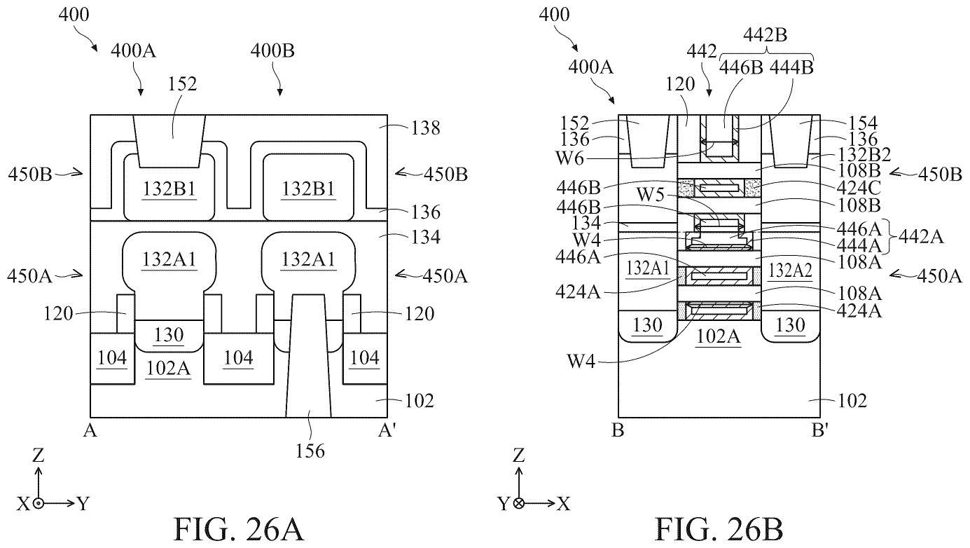

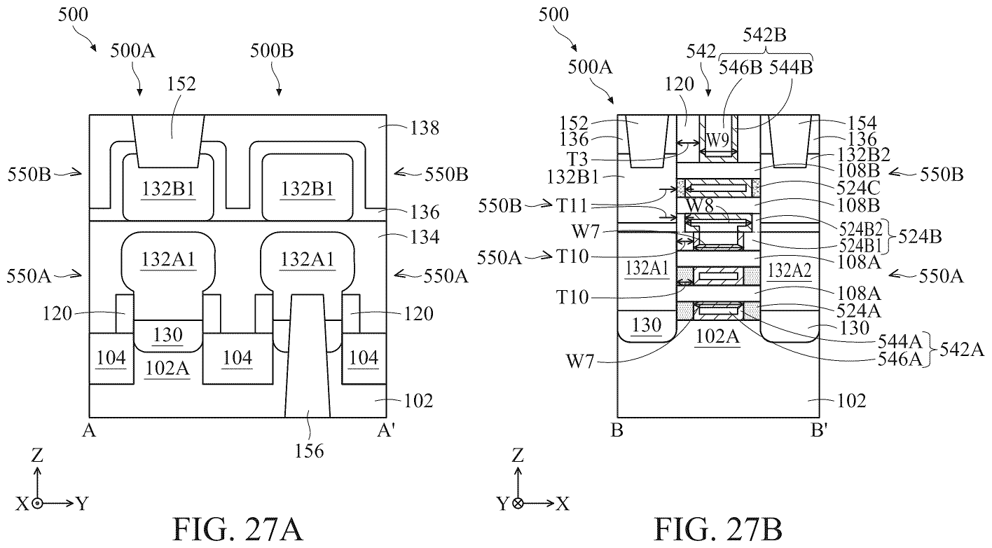

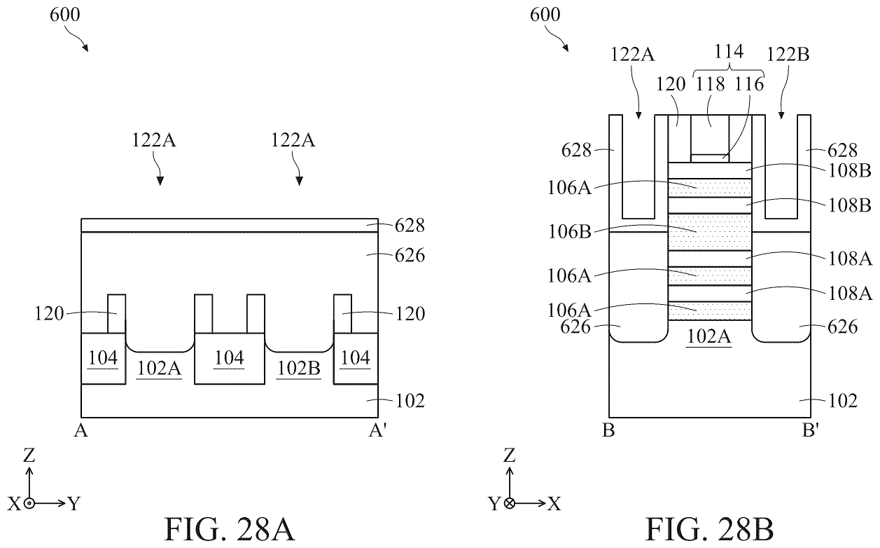

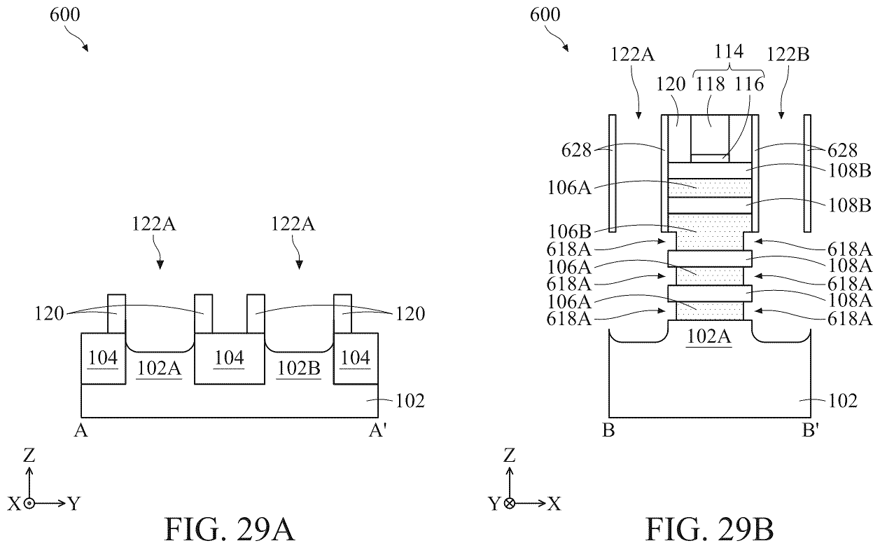

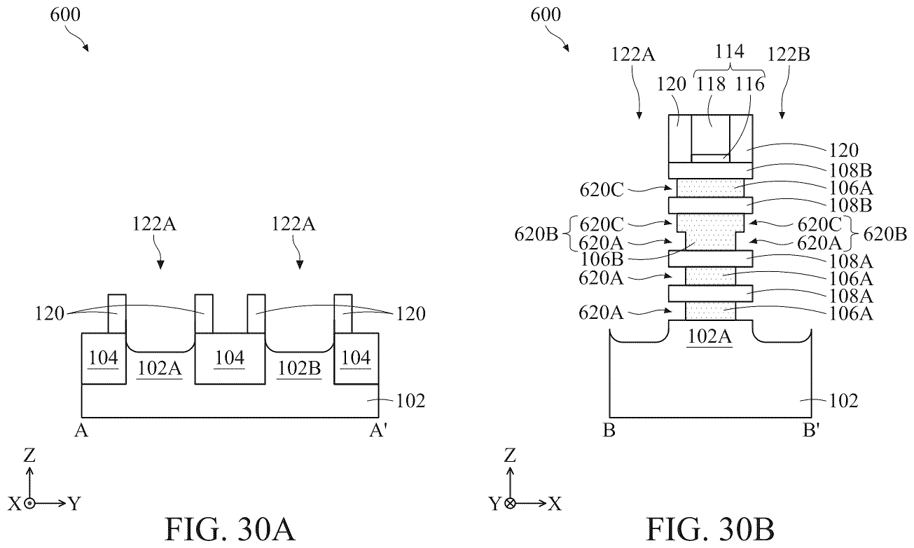

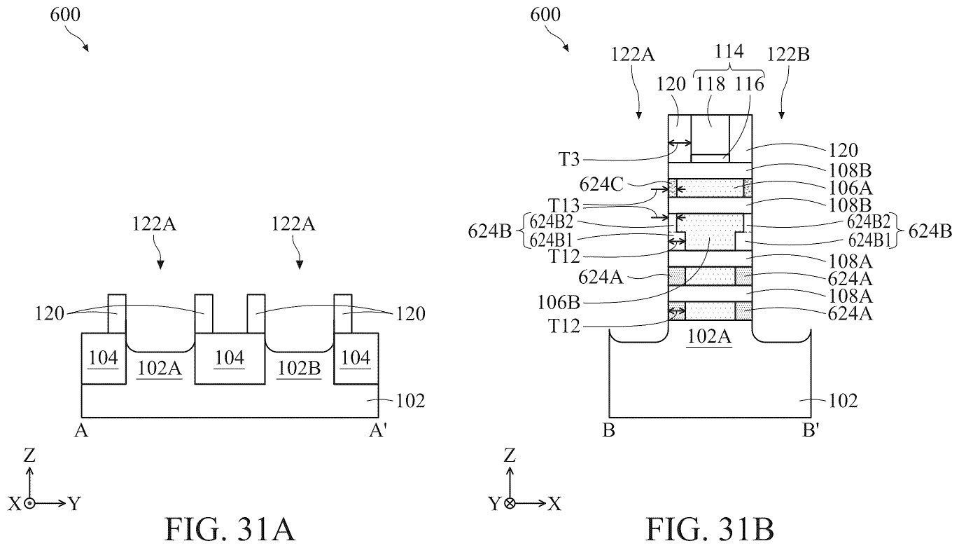

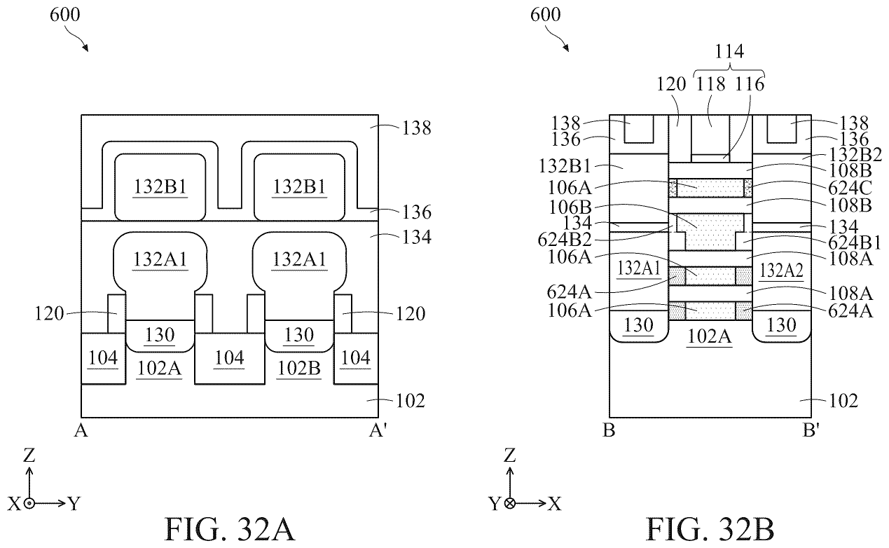

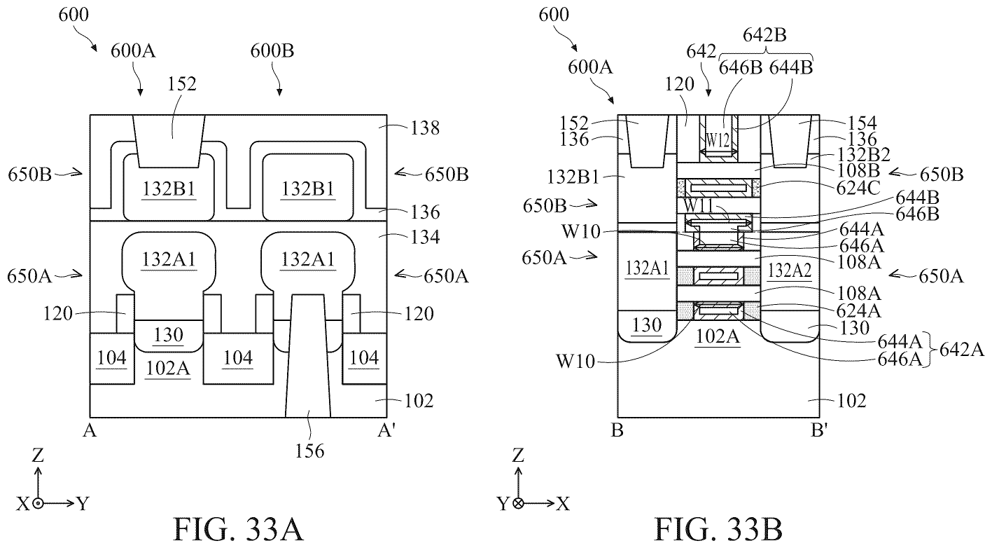

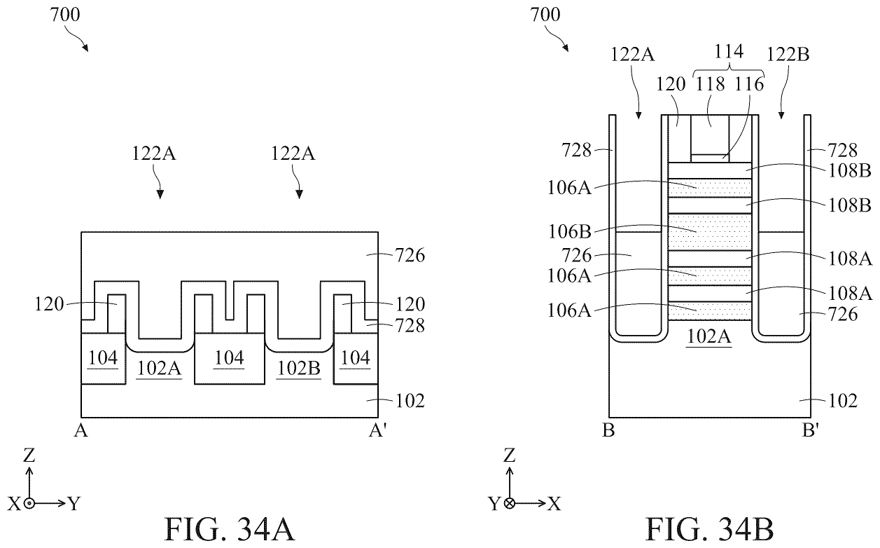

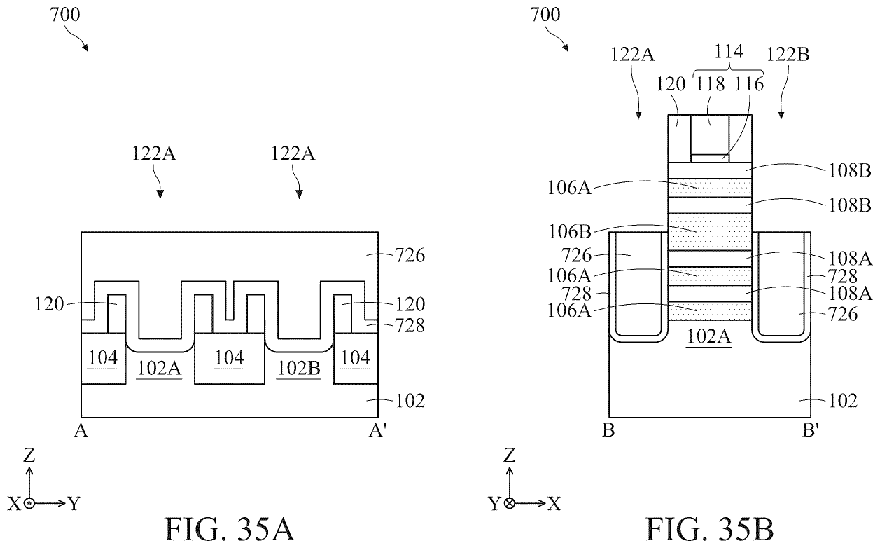

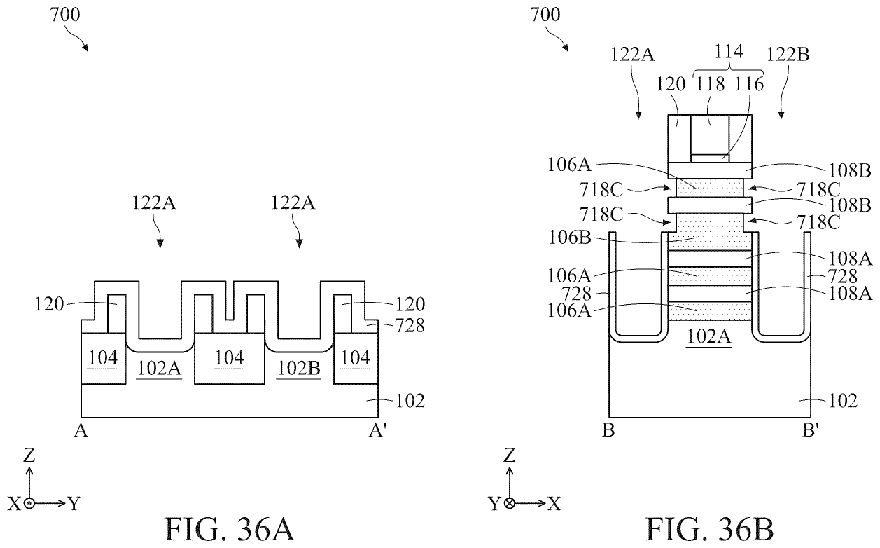

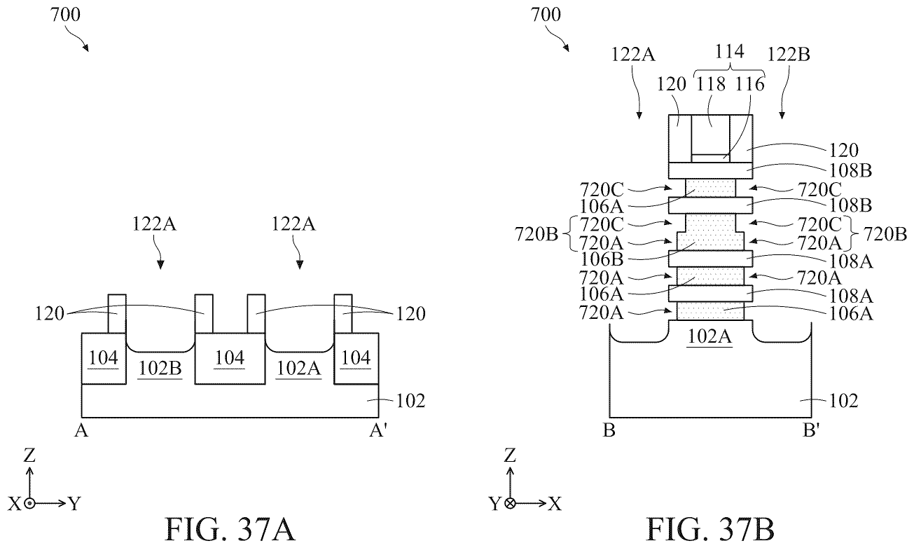

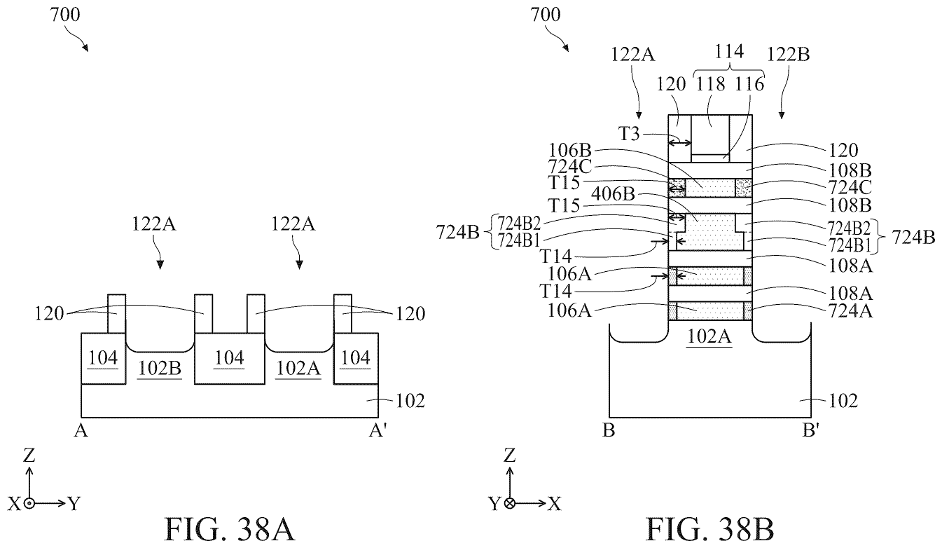

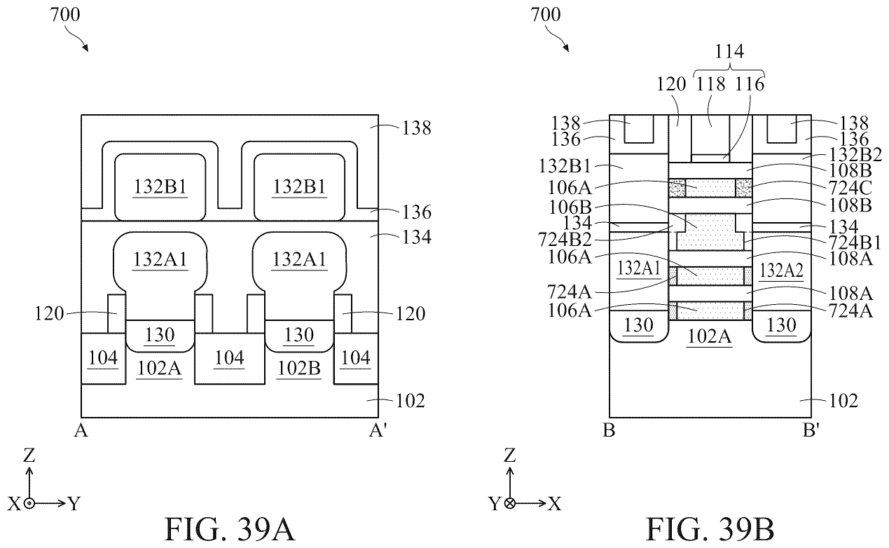

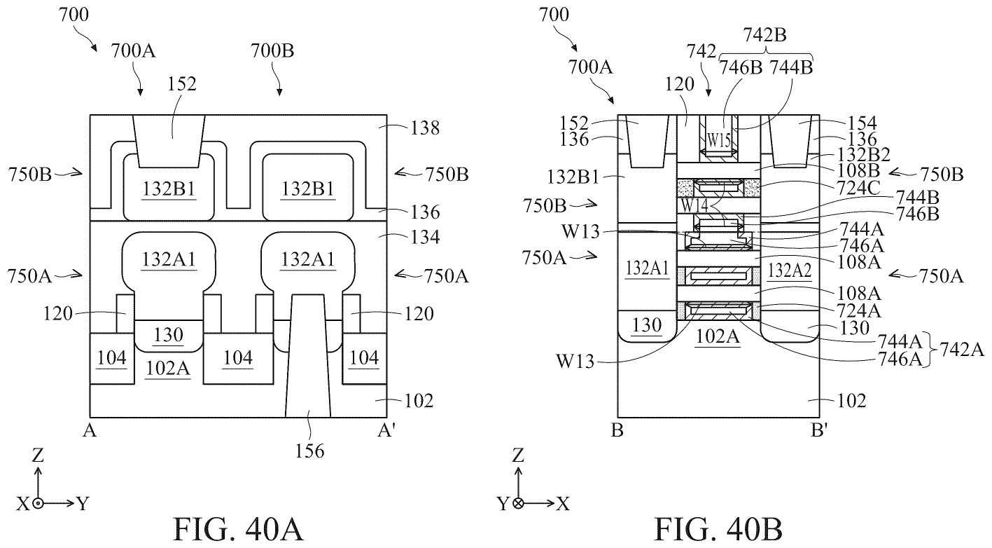

After forming the gate structure 142, the transistors in the CFET are formed. For example, the source/drain features 132A1 and 132A2, the semiconductor layers 108A, and the gate structures 142A constitute the transistor 150A, and the source/drain features 132B1 and 132B2, the semiconductor layers 108B, and the gate structures 142B constitute the transistor 150B over the transistor 150A, as shown in FIG. 14A (and FIG. 15A below). One transistor 150A and one transistor 150B constitute a CFET. In some embodiments, the workpiece 100 includes two CFETs, for example, FIG. 15A below shows a CFET 100A and a CFET 100B. In some embodiments, the transistors 150A and 150B are PFET and NFET in the CFET, respectively. In other embodiments, the transistors 150A and 150B are NFET and PFET in the CFET, respectively.

In some embodiments, the inner spacers of the transistor 150A (i.e., the recessed inner spacers 124A′ and the recessed first portions 124B1 of the recessed inner spacers 124B′) have the thickness T1 that is thinner than the thickness T2 of the inner spacers of the transistor 150B (i.e., the inner spacers 124C and the second portions 124B2 of the recessed inner spacers 124B′), as shown in FIG. 14A. In the embodiments where the transistor 150A is PFET and the transistor 150B is NFET, the thinner thickness T1 may improve DC performance of the PFET (i.e., the transistor 150A), and the thicker thickness T1 may reduce the parasitic capacitance of the NFET (i.e., the transistor 150B). In the embodiments where the transistor 150A is NFET and the transistor 150B is PFET, the thinner thickness T1 may improve DC performance of the NFET (i.e., the transistor 150A), and the thicker thickness T1 may reduce the parasitic capacitance of the PFET (i.e., the transistor 150B).

In the embodiments where the thickness T3 of the gate spacers 120 is greater than the thicknesses T1 and T2 of the inner spacers 124, the parasitic capacitance of the CFET can be reduced further. In the embodiments where the k value of the gate spacers 120 is lower than the inner spacers 124, the parasitic capacitance of the CFET can be reduced further. In some embodiments, the material of the inner spacers 124C is different from the recessed inner spacers 124A′. For example, the k value of the recessed inner spacers 124A′ is lower when the transistor 150A is PFET, alternatively, the k value of the inner spacers 124C is lower when the transistor 150B is PFET.

Referring to FIGS. 15A and 15B, the interconnection structure is formed in the workpiece 100, in accordance with some embodiments. For example, source/drain contacts 152 and 154 are formed on the frontside of the workpiece 100, and the source/drain contact 156 is formed on the backside of the workpiece 100.

In some embodiments, the source/drain contact 152 is formed to pass through the ILD layer 138, the CESLs 136, and portions of the source/drain feature 132B1, so as to contact the source/drain feature 132B1. In some embodiments, the source/drain contact 152 is electrically connected to the source/drain feature 132B1 of the CFET 100A. In some embodiments, the source/drain contact 154 is formed to pass through the ILD layer 138, the CESLs 136, and portions of the source/drain feature 132B2, so as to contact the source/drain feature 132B2. In some embodiments, the source/drain contact 154 is electrically connected to the source/drain feature 132B2 of the CFET 100A. In some embodiments, the source/drain contact 156 is formed to pass through the substrate 102, the bottom isolation layer 130, and portions of the source/drain feature 132A1, so as to contact the source/drain feature 132A1. In some embodiments, the source/drain contact 156 is electrically connected to the source/drain feature 132A1 of the CFET 100B.

The formation of the source/drain contact 152 may include forming a contact opening passing through the ILD layer 138 and the CESLs 136 and partially extending into the source/drain feature 132B1, so as to expose the source/drain feature 132B1. Then, a conductive material of the source/drain contact 152 may be deposited in the contact opening by a deposition process to form the source/drain contact 152. The formation of the source/drain contact 154 may include forming a contact opening passing through the ILD layer 138 and the CESLs 136 and partially extending into the source/drain feature 132B2, so as to expose the source/drain feature 132B2. Then, a conductive material of the source/drain contact 154 may be deposited in the contact opening by a deposition process to form the source/drain contact 154. The formation of the source/drain contact 156 may include forming a contact opening passing through the substrate 102 and the bottom isolation layers 130 and partially extending into the source/drain feature 132A1, so as to expose the source/drain feature 132A1. Then, a conductive material of the source/drain contact 156 may be deposited in the contact opening by a deposition process to form the source/drain contact 156.

The source/drain contacts 152, 154, and 156 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. In some embodiments, the source/drain contacts 152, 154, and 156 may each include a single conductive material layer or multiple conductive layers.

FIGS. 16A to 20B illustrate the workpiece 200 at various fabrication stages, in accordance with some alternative embodiments of the present disclosure. FIGS. 16A, 17A, 18A, 19A, and 20A are Y-Z cross-sectional views of the workpiece 200 at various fabrication stages along line A-A′ of FIG. 2, in accordance with some embodiments. FIGS. 16B, 17B, 18B, 19B, and 20B are X-Z cross-sectional views of the workpiece 200 at various fabrication stages along line B-B′ of FIG. 2, in accordance with some embodiments. Similar to the workpiece 100, the workpiece 200 may be referred to as the semiconductor structure 200 as the context requires. The fabrication stage shown in FIGS. 16A and 16B follows the fabrication stage shown in FIGS. 8A and 8B. For the purpose of clarity, the inner spacers 124A, 124B, and 124C shown in FIG. 8B are relabeled as inner spacers 224A, 224B, and 224C (which may be collectively referred to as inner spacers 224) in the workpiece 200, as shown in FIG. 16B.

Referring to FIGS. 16A and 16B, after removing the polymer layers 126, the bottom isolation layers 130 and the source/drain features 132A are formed in the lower parts of the source/drain trenches 122 and below the cover spacers 128. The materials and methods used in forming the bottom isolation layers 130 and the source/drain features 132A have been discussed above with reference to FIGS. 10A and 10B, and are not repeated herein.

It should be noted that, in the fabrication stage shown in FIGS. 16A and 16B, the inner spacers 224 are not recessed, and thus the source/drain features 132A are in contact with the inner spacers 224A and 224B that are not recessed, and the bottom isolation layers 130 are in contact with the inner spacers 224A that are not recessed, in accordance with some embodiments. In some embodiments, since the inner spacers 224 are not recessed, sidewalls of the inner spacers 224A, 224B, and 224C are aligned with each other and sidewalls of the gate spacers 120 and the semiconductor layers 108.

Referring to FIGS. 17A and 17B, the cover spacers 128 are removed through a selective etching process, and then the ILD layer 134 is formed in the source/drain trenches 122, in accordance with some embodiments. The method used in removing the cover spacers 128 and the material and method used in forming the ILD layer 134 have been discussed above with reference to FIGS. 11A and 11B, and are not repeated herein.

Referring to FIGS. 18A and 18B, the inner spacers 224C and second portions of the inner spacers 224B are partially recesses, in accordance with some embodiments. In some embodiments, the inner spacers 224C and the second portions of the inner spacers 224B exposed in the source/drain trenches 122 are partially recessed through a selective etching process, and the inner spacers 224A and first portions of the inner spacers 224B covered by the source/drain features 132A and the ILD layer 134 are not etched. More specifically, the selective etching process is performed that selectively etches the side portions of the inner spacers 224C and the second portions of the inner spacers 224B exposed in the source/drain trenches 122, with minimal etching (or substantially no etching) of the semiconductor layers 108B and the ILD layer 134.

After the selective etching process, the inner spacers 224C are partially recessed to form recessed inner spacers 224C′. Similarly, the inner spacers 224B are partially recessed to form recessed inner spacers 224B′ that each includes a first portion 224B1 that is not recessed and a recessed second portion 224B2 that is partially recessed. In some embodiments, the recessed inner spacers 224C′ are vertically between the semiconductor layers 108B. In some embodiments, the recessed inner spacers 224B′ are between the topmost semiconductor layer 108A and the bottommost semiconductor layer 108B, wherein the first portions 224B1 are in contact with the topmost semiconductor layer 108A, and the recessed second portions 224B2 are in contact with the bottommost semiconductor layer 108B, as shown FIG. 18B.

In some embodiments, the inner spacers 224A and the first portions 224B1 of the recessed inner spacers 224B′ have a thickness T4 in the X-direction (horizontal dimension), and the recessed inner spacers 224C′ and the recessed second portions 224B2 of the recessed inner spacers 224B′ have a thickness T5 in the X-direction (horizontal dimension). In some embodiments, the thickness T4 is greater than the thickness T5 by about 0.5 nm to about 4 nm. In some embodiments, the gate spacers 120 have the thickness T3 in the X-direction, and the thickness T3 is greater than the thickness T4 by about 0.5 nm to about 4 nm. In some embodiments, the end portions of the semiconductor layers 108B protrude from the recessed inner spacers 224C′ and the recessed second portions 224B2, and are exposed in the source/drain trenches 122, as shown in FIG. 18B.

Referring to FIGS. 19A and 19B, the source/drain features 132B are formed in the source/drain trenches 122 and over the ILD layer 134, in accordance with some embodiments. The material and method used in forming the source/drain features 132B have been discussed above with reference to FIGS. 12A and 12B, and are not repeated herein.

In some embodiments, the source/drain features 132B are in contact with the recessed inner spacers 224C′ and the recessed second portions 224B2 of the recessed inner spacers 224B′. In further embodiments, the source/drain features 132B are in contact with top surfaces of the first portions 224B1 of the recessed inner spacers 224B′, wherein the top surfaces of the first portions 224B1 are generated due to the formation of the recessed second portion 224B2. In some embodiments, since the end portions of the semiconductor layers 108B protrude from the recessed inner spacers 224C′ and the recessed second portions 224B2, the end portions of the semiconductor layers 108B are surrounded by the source/drain features 132B.

Still referring to FIGS. 19A and 19B, the CESLs 136 are formed over the source/drain features 132B and the ILD layer 134, and the ILD layer 138 is formed over the CESLs 136 to fill the spaces between the source/drain features 132B, in accordance with some embodiments. The material and method used in forming the CESLs 136 and the ILD layer 138 have been discussed above with reference to FIGS. 12A and 12B, and are not repeated herein.

Referring to FIGS. 20A and 20B, the dummy gate structure 114 and the semiconductor layers 106 are removed to form the gate trench 140, and the gate structure 142 is formed in the gate trench 140, in accordance with some embodiments. The methods used in removing the dummy gate structure 114 and the semiconductor layers 106 have been discussed above with reference to FIGS. 13A and 13B, and the material and method used in forming the gate structure 142 have been discussed above with reference to FIGS. 14A and 14B, and are not repeated herein.

As described above, the gate structure 142A may be referred to as the first inner gate structure. In some embodiments, the gate structure 142A is in contact with the inner spacers 224A and the first portions 224B1 of the recessed inner spacers 224B′. As described above, the gate structure 142B may be divided into the outer gate structure and the second inner gate structure. In some embodiments, the outer gate structure of the gate structure 142B may be in contact with the gate spacers 120, and the second inner gate structure of the gate structure 142B may be in contact with the recessed inner spacers 224C′ and the recessed second portions 224B2 of the recessed inner spacers 224B′.

After forming the gate structure 142, the transistors in the CFET are formed. For example, in the workpiece 200, the source/drain features 132A1 and 132A2, the semiconductor layers 108A, and the gate structures 142A constitute the transistor 250A, and the source/drain features 132B1 and 132B2, the semiconductor layers 108B, and the gate structures 142B constitute the transistor 250B over the transistor 250A, as shown in FIGS. 20A and 20B. One transistor 250A and one transistor 250B constitute a CFET. In some embodiments, the workpiece 200 includes two CFETs, for example, FIGS. 20A and 20B show a CFET 200A and a CFET 200B. In some embodiments, the transistors 250A and 250B are PFET and NFET in the CFET, respectively. In other embodiments, the transistors 250A and 250B are NFET and PFET in the CFET, respectively.

In some embodiments, the inner spacers of the transistor 250B (i.e., the recessed inner spacers 224C′ and the recessed second portions 224B2 of the recessed inner spacers 224B′) have the thickness T5 that is thinner than the thickness T4 of the inner spacers of the transistor 250A (i.e., the inner spacers 224A and the first portions 224B1 of the recessed inner spacers 224B′) (see FIG. 18B). In the embodiments where the transistor 250A is PFET and the transistor 250B is NFET, the thinner thickness T5 may improve DC performance of the NFET (i.e., the transistor 250B), and the thicker thickness T4 may reduce the parasitic capacitance of the PFET (i.e., the transistor 250A). In the embodiments where the transistor 250A is NFET and the transistor 250B is PFET, the thinner thickness T5 may improve DC performance of the PFET (i.e., the transistor 250B), and the thicker thickness T4 may reduce the parasitic capacitance of the NFET (i.e., the transistor 250A).

In the embodiments where the thickness T3 of the gate spacers 120 is greater than the thicknesses T4 and T5 of the inner spacers 224, the parasitic capacitance of the CFET can be reduced further. In the embodiments where the k value of the gate spacers 120 is lower than the inner spacers 224, the parasitic capacitance of the CFET can be reduced further. In some embodiments, the material of recessed inner spacers 224C′ is different from the inner spacers 224A. For example, the k value of the inner spacers 224A is lower when the transistor 250A is PFET, alternatively, the k value of the recessed inner spacers 224C′ is lower when the transistor 250B is PFET.

Still referring to FIGS. 20A and 20B, the interconnection structure is formed in the workpiece 200, in accordance with some embodiments. For example, source/drain contacts 152 and 154 are formed on the frontside of the workpiece 200, and the source/drain contact 156 is formed on the backside of the workpiece 200. The methods used in forming the source/drain contacts 152, 154, and 156 have been discussed above with reference to FIGS. 15A and 15B, and are not repeated herein.

FIGS. 21 to 26B illustrate the workpiece 400 at various fabrication stages, in accordance with some alternative embodiments of the present disclosure. FIG. 21 is a perspective view of the workpiece 400 at a fabrication stage, in accordance with some embodiments. FIGS. 22A, 23A, 24A, 25A, and 26A are Y-Z cross-sectional views of the workpiece 400 at various fabrication stages along line A-A′ of FIG. 21, in accordance with some embodiments. FIGS. 22B, 23B, 24B, 25B, and 26B are X-Z cross-sectional views of the workpiece 400 at various fabrication stages along line B-B′ of FIG. 21, in accordance with some embodiments. Similar to the workpiece 100, the workpiece 400 may be referred to as the semiconductor structure 400. The workpiece 400 shown in FIG. 21 may be similar to the workpiece 100 shown in FIG. 2, except the fin structures 112A and 112B shown in FIG. 2 are replaced by fin structures 412A and 412B (which may be collectively referred to as fin structures 412) shown in FIG. 21.

In some embodiments, each of the fin structures 412 includes a base fin (i.e., base portions 102A and 102B) formed from the substrate 102, a first stack 402 formed on the base fin, a second stack 404 formed on the first stack 402, and the hard mask layer 110 formed on the second stack 404, as shown in FIG. 21. The first stack 402 includes the semiconductor layers 406A and 108A that are alternately stacked in the Z-direction, and the second stack 404 includes the semiconductor layers 406B and 108B that are alternately stacked in the Z-direction.

In some embodiments, the formation of the fin structures 412 includes forming a stack assembly that includes a first portion and a second portion on the first portion, wherein the first portion includes the semiconductor layers 406A and 108A that are stacked in an alternating manner in the Z-direction, and the second portion includes the semiconductor layers 406B and 108B that are stacked in an alternating manner in the Z-direction. Then, in some embodiments, the substrate 102 and the stack assembly are patterned to form the fin structures 412A and 412B. The method used in forming the stack assembly is the same as or similar to those of the stack 103, and the method used in forming the fin structures 412 is the same as or similar to those of the fin structures 112, and are not repeated herein. In some embodiments, the topmost semiconductor layer 406A is in direct contact with the bottommost semiconductor layer 406B, as shown in FIG. 21. That is, the bottommost semiconductor layer 406B is grown from the topmost semiconductor layer 406A.

In some embodiments, the semiconductor layers 108 are formed of Si, and the semiconductor layers 406A and 406B (which may be collectively referred to as semiconductor layers 406) are formed of SiGe. In some embodiments, semiconductor layers 406A and 406B have different composition to achieve desired etching selectivity. For example, in some embodiments, the Ge concentration of the semiconductor layers 406B is higher than the Ge concentration of the semiconductor layers 406A, such that the etching rate of the semiconductor layers 406B is higher than the etching rate of the semiconductor layers 406A during the etching process. In some embodiments, the Ge concentration of the semiconductor layers 406B is higher than the Ge concentration of the semiconductor layers 406A by more than 2%.

Referring to FIGS. 22A and 22B, the hard mask layer 110 is removed and the dummy gate structure 114 is formed over the fin structures 412, in accordance with some embodiments. The method used in removing the hard mask layer 110 and the material and method used in forming the dummy gate structure 114 have been discussed above with reference to FIGS. 3A and 3B, and are not repeated herein.

Still referring to FIGS. 22A and 22B, after forming of the dummy gate structure 114, the gate spacers 120 are formed on sidewalls of the dummy gate structure 114, and over the top surfaces and on the sidewalls of the fin structures 412, in accordance with some embodiments. The material and method used in forming the gate spacers 120 have been discussed above with reference to FIGS. 4A and 4B, and are not repeated herein.

Still referring to FIGS. 22A and 22B, the fin structures 412 are recessed to form source/drain trenches 122 in the fin structures 412, in accordance with some embodiments. In some embodiments, in each of the fin structures 412, the source/drain trenches 122 include the source/drain trench 122A and the source/drain trench 122B that are on opposite sides of the dummy gate structure 114 in the X-direction. The method used in forming the source/drain trenches 122A and 122B has been discussed above with reference to FIGS. 5A and 5B, and are not repeated herein.

Referring to FIGS. 23A and 23B, the semiconductor layers 406 exposed in the source/drain trenches 122 are partially recessed by a selective etching process, in accordance with some embodiments. Specifically, the selective etching process is performed that selectively etches the side portions of the semiconductor layers 406 below the gate spacers 120 through the source/drain trenches 122, with minimal etching (or substantially no etching) of semiconductor layers 108.

After the selective etching process, the semiconductor layers 406A are partially etched to form inner spacer recesses 420A, and the semiconductor layers 406B are partially etched to form inner spacer recesses 420C, as shown in FIG. 23B. In some embodiments, the inner spacer recesses 420A over the topmost semiconductor layer 108A and the inner spacer recesses 420C below the bottommost semiconductor layer 108B may constitute inner spacer recesses 420B. In the embodiments where the Ge concentration of the semiconductor layers 406B is greater than the semiconductor layers 406A, the semiconductor layers 406B are etched more than the semiconductor layers 406A due to the etching selectivity. Therefore, the horizontal dimensions of the inner spacer recesses 420C are greater than the horizontal dimensions of the inner spacer recesses 420A in the X-direction, as shown in FIG. 23B.

Referring to FIGS. 24A and 24B, inner spacers 424A, 424B, and 424C (which may be collectively referred to as inner spacers 424) are formed in the inner spacer recesses 420A, 420B, and 420C, respectively, in accordance with some embodiments. More specifically, the inner spacers 424A may be formed in the inner spacer recesses 420A that are between the semiconductor layers 108A and between the semiconductor layer 108A and the substrate 102. The inner spacers 424B may include first portions 424B1 formed in the inner spacer recesses 420A that are over the topmost semiconductor layer 108A, and second portions 424B2 formed in the inner spacer recesses 420C that are below the bottommost semiconductor layer 108B. The inner spacers 424C may be formed in the inner spacer recesses 420C between semiconductor layers 108B. The material and method used in forming the inner spacers 424 are the same as or similar to those of the inner spacers 124, and are not repeated herein.

Since the horizontal dimensions of the inner spacer recesses 420A and 420C are different in the X-direction, the horizontal dimensions of the inner spacers 424A, 424B, and 424C formed in the inner spacer recesses 420A and 420C are different in the X-direction. In some embodiments, the inner spacers 424A and the first portions 424B1 of the inner spacers 424B have a thickness T8 in the X-direction, and the inner spacers 424C and the second portions 424B2 of the inner spacers 424B have a thickness T9 in the X-direction. In some embodiments, the thickness T9 is greater than the thickness T8 by about 0.5 nm to about 4 nm. In some embodiments, the gate spacers 120 have the thickness T3 in the X-direction, and the thickness T3 is greater than the thickness T9 by about 0.5 nm to about 4 nm.

Referring to FIGS. 25A and 25B, the bottom isolation layers 130 and the source/drain features 132A are formed, in accordance with some embodiments. The formation of the bottom isolation layers 130 and the source/drain features 132A may include forming the polymer layer 126 and the cover spacers 128 and removing the polymer layer 126 and the horizontal portions of the cover spacers 128, which have been discussed above with reference to FIGS. 7A to 8B, and are not repeated herein.

Then, the bottom isolation layers 130 and the source/drain features 132A may be formed in the lower parts of the source/drain trenches 122, while the sidewalls of the gate spacers 120 and the semiconductor layers 108B are covered by the cover spacers 128. The materials and methods used in forming the bottom isolation layers 130 and the source/drain features 132A have been discussed above with reference to FIGS. 10A and 10B, and are not repeated herein.

Still referring to FIGS. 25A and 25B, the cover spacers 128 are removed through a selective etching process, and then the ILD layer 134 is formed in the source/drain trenches 122, in accordance with some embodiments. The method used in removing cover spacers 128 and the material and method used in forming the ILD layer 134 have been discussed above with reference to FIGS. 11A and 11B, and are not repeated herein.

Still referring to FIGS. 25A and 25B, the source/drain features 132B are formed in the source/drain trenches 122 and over the ILD layer 134, in accordance with some embodiments. The material and method used in forming the source/drain features 132B have been discussed above with reference to FIGS. 12A and 12B, and are not repeated herein.

In some embodiments, since the inner spacers 424A, 424B, and 424C are not recessed through the source/drain trenches 122, the sidewalls of the inner spacers 424A, 424B, and 424C are aligned with each other and the sidewalls of the gate spacers 120 and the semiconductor layers 108. In some embodiments, the source/drain features 132A are in contact with the inner spacers 424A and the first portions 424B1 of the inner spacers 424B, and the source/drain features 132B are in contact with the inner spacers 424C and the second portions 424B2 of the inner spacers 424B.

Still referring to FIGS. 25A and 25B, the CESLs 136 are formed over the source/drain features 132B and the ILD layer 134, and the ILD layer 138 is formed over the CESLs 136 to fill the spaces between the source/drain features 132B, in accordance with some embodiments. The material and method used in forming the CESLs 136 and the ILD layer 138 have been discussed above with reference to FIGS. 12A and 12B, and are not repeated herein.

Referring to FIGS. 26A and 26B, the dummy gate structure 114 and the semiconductor layers 406 are removed to form a gate trench, and a gate structure 442 including a gate structure 442A and a gate structure 442B are formed in the gate trench, in accordance with some embodiments. The methods used in removing the dummy gate structure 114 and the semiconductor layers 406 to form the gate trench are the same as or similar to those of forming the gate trench 140, and are not repeated herein.

In some embodiments, the gate structure 442B is over the gate structure 442A. In some embodiments, the gate structure 442A includes a gate dielectric layer 444A and a gate electrode layer 446A, and the gate structure 442B includes a gate dielectric layer 444B and a gate electrode layer 446B. The materials and methods used in forming the gate dielectric layers 444A and 444B and the gate electrode layers 446A and 446B are the same as or similar to those of the gate dielectric layers 144A and 144B and the gate electrode layers 146A and 146B, respectively, and are not repeated herein.

In some embodiments, the gate dielectric layer 444A wraps around each of the semiconductor layers 108A, and the gate electrode layer 446A wraps around the gate dielectric layers 444A. Moreover, the gate dielectric layer 444A is also formed on the sidewalls of the inner spacers 424A and the first portions 424B1 of the inner spacers 424B, as well as over the top surfaces of the substrate 102 and the isolation structures 104. In some embodiments, the gate dielectric layer 444A is in contact with bottom surfaces of the second portions 424B2 of the inner spacers 424B, wherein these bottom surfaces are generated due to the difference of horizontal dimensions between the first portions 424B1 and the second portions 424B2. In some embodiments, the gate dielectric layer 444B wraps around each of the semiconductor layers 108B, and the gate electrode layer 446B wraps around the gate dielectric layer 444B. Moreover, the gate dielectric layer 444B is also formed on the sidewalls of the inner spacers 424C, the second portions 424B2 of the inner spacers 424B, and the gate spacers 120.

Similar to the gate structure 142, the gate structure 442A may be referred to as first inner gate structure, and the gate structure 442B may be divided into an outer gate structure and a second inner gate structure. The gate structure 442A may be in contact with the inner spacers 424A and first portions 424B1 of the inner spacers 424B. The outer gate structure of the gate structure 442B may be in contact with the gate spacers 120, and the second inner gate structure of the gate structure 442B may be in contact with the inner spacers 424C and the second portions 424B2 of the inner spacers 424B.

In some embodiments, in X-direction, the gate structure 442A (first inner gate structure) has a width W4, the second inner gate structure of the gate structure 442B has a width W5, and the outer gate structure of the gate structure 442B has a width W6, as shown in FIG. 26B. In some embodiments, the width W4 is greater than the width W5 by about 0.5 nm to about 4 nm. In some embodiments, the width W5 is greater than the width W6 by about 0.5 nm to about 4 nm. In some embodiments, the width W6 is smaller than the width W4 and/or the width W5 by about 0.5 nm to about 8 nm.

After forming the gate structure 442, the transistors in the CFET are formed. For example, in the workpiece 400, the source/drain features 132A1 and 132A2, the semiconductor layers 108A, and the gate structures 442A constitute the transistor 450A, and the source/drain features 132B1 and 132B2, the semiconductor layers 108B, and the gate structures 442B constitute the transistor 450B over the transistor 450A, as shown in FIGS. 26A and 26B. One transistor 450A and one transistor 450B constitute a CFET. In some embodiments, the workpiece 400 includes two CFETs, for example, FIGS. 26A and 26B show a CFET 400A and a CFET 400B. In some embodiments, the transistors 450A and 450B are PFET and NFET in the CFET, respectively. In other embodiments, the transistors 450A and 450B are NFET and PFET in the CFET, respectively.

In some embodiments, the inner spacers of the transistor 450A (i.e., the inner spacers 424A and the first portions 424B1 of the inner spacers 424B) have the thickness T8 that is thinner than the thickness T9 of the inner spacers of the transistor 450B (i.e., the inner spacers 424C and the second portions 424B2 of the inner spacers 424B) (see FIG. 24B). In the embodiments where the transistor 450A is PFET and the transistor 450B is NFET, the thinner thickness T8 may improve DC performance of the PFET (i.e., the transistor 450A), and the thicker thickness T9 may reduce the parasitic capacitance of the NFET (i.e., the transistor 450B). In the embodiments where the transistor 450A is NFET and the transistor 450B is PFET, the thinner thickness T8 may improve DC performance of the NFET (i.e., the transistor 450A), and the thicker thickness T9 may reduce the parasitic capacitance of the PFET (i.e., the transistor 450B).

In the embodiments where the thickness T3 of the gate spacers 120 is greater than the thicknesses T8 and T9 of the inner spacers 424, the parasitic capacitance of the CFET can be reduced further. In the embodiments where the k value of the gate spacers 120 is lower than the inner spacers 424, the parasitic capacitance of the CFET can be reduced further. In some embodiments, the material of the inner spacers 424C is different from that of the inner spacers 424A. For example, the k value of the inner spacers 424A is lower when the transistor 450A is PFET, alternatively, the k value of the inner spacers 424C is lower when the transistor 450B is PFET.

In some embodiments, the inner gate structure of the transistor 450A (i.e., the gate structure 442A) have the width W4 that is wider than the width W5 of the inner gate structure of the transistor 450B (i.e., the second inner gate structure of the gate structure 442B), as shown in FIG. 26B. In the embodiments where the transistor 450A is PFET and the transistor 450B is NFET, the wider width W4 may mitigate DIBL of the PFET (i.e., the transistor 450A). In the embodiments where the transistor 450A is NFET and the transistor 450B is PFET, the wider width W4 may mitigate DIBL of the NFET (i.e., the transistor 450A).

Still referring to FIGS. 26A and 26B, the interconnection structure is formed in the workpiece 400, in accordance with some embodiments. For example, source/drain contacts 152 and 154 are formed on the frontside of the workpiece 400, and the source/drain contact 156 is formed on the backside of the workpiece 400. The methods used in forming the source/drain contacts 152, 154, and 156 have been discussed above with reference to FIGS. 15A and 15B, and are not repeated herein.

FIGS. 27A and 27B are cross-sectional views of a semiconductor structure 500 along lines A-A′ and B-B′ of FIG. 21, respectively, in accordance with some alternative embodiments. The semiconductor structure 500 shown in FIGS. 27A and 27B may be similar to the workpiece 400 shown in FIGS. 26A and 26B, except the inner spacers 424 and the gate structure 442 shown in FIGS. 26A and 26B are replaced by inner spacers 524 and a gate structure 542 shown in FIGS. 27A and 27B.

The formation of inner spacers 524 includes adjusting the Ge concentrations in the semiconductor layers 406A and 406B. For example, the Ge concentrations of the semiconductor layers 406A and 406B are exchanged, such that the semiconductor layers 406A have higher Ge concentration than the semiconductor layers 406B. In this way, horizontal dimensions of the inner spacer recesses formed in the semiconductor layers 406A are greater than horizontal dimensions of the inner spacer recesses formed in the semiconductor layers 406B during the fabrication stage shown in FIGS. 23A and 23B. As a result, the inner spacers 524 formed in these inner spacer recesses have the opposite dimensional relationship to the inner spacers 424. The material and method used in forming the inner spacers 524 are the same as or similar to those of the inner spacers 424, and are not repeated herein.

In some embodiments, the inner spacers 524 include inner spacers 524A, 524B, and 524C, as shown in FIG. 27B. More specifically, the inner spacers 524A may be formed between the semiconductor layers 108A as well as between the semiconductor layer 108A and the substrate 102. The inner spacers 524B may include first portions 524B1 formed over the topmost semiconductor layer 108A, and second portions 524B2 formed over the first portions 524B1 and below the bottommost semiconductor layer 108B. The inner spacers 424C may be formed between the semiconductor layers 108B.

In some embodiments, the inner spacers 524A and the first portions 524B1 of the inner spacers 524B have a thickness T10 in the X-direction, and the inner spacers 524C and the second portions 524B2 of the inner spacers 524B have a thickness T11 in the X-direction. In some embodiments, the thickness T10 is greater than the thickness T11 by about 0.5 nm to about 4 nm. In some embodiments, the gate spacers 120 have the thickness T3 in the X-direction, and the thickness T3 is greater than the thickness T10 by about 0.5 nm to about 4 nm.

In some embodiments, sidewalls of the inner spacers 524A, 524B, and 524C are aligned with each other and the sidewalls of the gate spacers 120 and the semiconductor layers 108, as shown in FIG. 27B. In some embodiments, the source/drain features 132A are in contact with the inner spacers 524A and the first portions 524B1 of the inner spacers 524B, and the source/drain features 132B are in contact with the inner spacers 524C and the second portions 524B2 of the inner spacers 524B.

In some embodiments, the gate structure 542 includes a gate structure 542A and a gate structure 542B over the gate structure 542A. In some embodiments, the gate structure 542A includes a gate dielectric layer 544A and a gate electrode layer 546A, and the gate structure 542B includes a gate dielectric layer 544B and a gate electrode layer 546B. The materials and methods used in forming the gate dielectric layers 544A and 544B and the gate electrode layers 546A and 546B are the same as or similar to those of the gate dielectric layers 144A and 144B and the gate electrode layers 146A and 146B, respectively, and are not repeated herein.

In some embodiments, the gate dielectric layer 544A wraps around each of the semiconductor layers 108A, and the gate electrode layer 546A wraps around the gate dielectric layers 544A. Moreover, the gate dielectric layer 544A is also formed on the sidewalls of the inner spacers 524A and the first portions 524B1 of the inner spacers 524B, as well as over the top surfaces of the substrate 102 and the isolation structures 104. In some embodiments, the gate dielectric layer 544B wraps around each of the semiconductor layers 108B, and the gate electrode layer 546B wraps around the gate dielectric layer 544B. Moreover, the gate dielectric layer 544B is also formed on the sidewalls of the inner spacers 524C, the second portions 524B2 of the inner spacers 524B, and the gate spacers 120. In some embodiments, the gate dielectric layer 544B is in contact with top surfaces of the first portions 524B1 of the inner spacers 524B, wherein these top surfaces are generated due to the difference of horizontal dimensions between the first portions 524B1 and the second portions 524B2.

Similar to the gate structure 142, the gate structure 542A may be referred to as first inner gate structure, and the gate structure 542B may be divided into an outer gate structure and a second inner gate structure. The gate structure 542A may be in contact with the inner spacers 524A and first portions 524B1 of the inner spacers 524B. The outer gate structure of the gate structure 542B may be in contact with gate spacers 120, and the second inner gate structure of the gate structure 542B may be in contact with the inner spacers 524C and the second portions 524B2 of the inner spacers 524B.

In some embodiments, in the X-direction, the gate structure 542A (first inner gate structure) has a width W7, the second inner gate structure of the gate structure 542B has a width W8, and the outer gate structure of the gate structure 542B has a width W9 in the X-direction, as shown in FIG. 27B. In some embodiments, the width W8 is greater than the width W7 by about 0.5 nm to about 4 nm. In some embodiments, the width W7 is greater than the width W9 by about 0.5 nm to about 4 nm. In some embodiments, the width W9 is smaller than the width W7 and/or the width W8 by about 0.5 nm to about 8 nm.

In the semiconductor structure 500, the source/drain features 132A1 and 132A2, the semiconductor layers 108A, and the gate structures 542A constitute a transistor 550A, and the source/drain features 132B1 and 132B2, the semiconductor layers 108B, and the gate structures 542B constitute a transistor 550B over the transistor 550A, as shown in FIGS. 27A and 27B. One transistor 550A and one transistor 550B constitute a CFET. In some embodiments, the semiconductor structure 500 includes CFETs 500A and 500B. In some embodiments, the transistors 550A and 550B are PFET and NFET in the CFET, respectively. In other embodiments, the transistors 550A and 550B are NFET and PFET in the CFET, respectively.

In some embodiments, the inner spacers of the transistor 550B (i.e., the inner spacers 524C and the second portions 524B2 of the inner spacers 524B) have the thickness T11 that is thinner than the thickness T10 of the inner spacers of the transistor 550A (i.e., the inner spacers 524A and the first portions 524B1 of the inner spacers 524B), as shown in FIG. 27B. In the embodiments where the transistor 550A is PFET and the transistor 550B is NFET, the thinner thickness T11 may improve DC performance of the NFET (i.e., the transistor 550B), and the thicker thickness T10 may reduce the parasitic capacitance of the PFET (i.e., the transistor 550A). In the embodiments where the transistor 550A is NFET and the transistor 550B is PFET, the thinner thickness T11 may improve DC performance of the PFET (i.e., the transistor 550B), and the thicker thickness T10 may reduce the parasitic capacitance of the NFET (i.e., the transistor 550A).

In the embodiments where the thickness T3 of the gate spacers 120 is greater than the thicknesses T10 and T11 of the inner spacers 524, the parasitic capacitance of the CFET can be reduced further. In the embodiments where the k value of the gate spacers 120 is lower than the inner spacers 524, the parasitic capacitance of the CFET can be reduced further. In some embodiments, the material of the inner spacers 524C is different from that of the inner spacers 524A. For example, the k value of the inner spacers 524A is lower when the transistor 550A is PFET, alternatively, the k value of the inner spacers 524C is lower when the transistor 550B is PFET.

In some embodiments, the inner gate structure of the transistor 550B (i.e., the second inner gate structure of the gate structure 542B) have the width W8 that is wider than the width W7 of the inner gate structure of the transistor 550A (i.e., the gate structure 542A), as shown in FIG. 27B. In the embodiments where the transistor 550A is PFET and the transistor 550B is NFET, the wider width W8 may mitigate DIBL of the NFET (i.e., the transistor 550B). In the embodiments where the transistor 550A is NFET and the transistor 550B is PFET, the wider width W8 may mitigate DIBL of the PFET (i.e., the transistor 550B).

FIGS. 28A to 33B illustrate the workpiece 600 at various fabrication stages, in accordance with some alternative embodiments of the present disclosure. FIGS. 28A, 29A, 30A, 31A, 32A, and 33A are Y-Z cross-sectional views of the workpiece 600 at fabrication stages along line A-A′ of FIG. 2, in accordance with some embodiments. FIGS. 28B, 29B, 30B, 31B, 32B, and 33B are X-Z cross-sectional views of the workpiece 600 at various fabrication stages along line B-B′ of FIG. 2, in accordance with some embodiments. Similar to the workpiece 100, the workpiece 600 may be referred to as the semiconductor structure 600. The fabrication stage shown in FIGS. 28A and 28B follows the fabrication stage shown in FIGS. 5A and 5B.

Referring to FIGS. 28A and 28B, polymer layers 626 and cover spacers 628 are formed in the source/drain trenches 122, in accordance with some embodiments. More specifically, the polymer layers 626 are first formed in lower parts of the source/drain trenches 122 to cover the top surfaces of the substrate 102 and the sidewalls of the semiconductor layers 108A. In some embodiments, top surfaces of the polymer layers 626 are lower than the semiconductor layers 108B. Then, the cover spacers 628 are conformally formed over the polymer layers 626 and on the sidewalls of the semiconductor layers 108B, the gate spacers 120, and the semiconductor layers 106 which are exposed by the polymer layers 626 and source/drain trenches 122. The materials and methods used in forming the polymer layers 626 and the cover spacers 628 are the same as or similar to those of the polymer layers 126 and the cover spacers 128, respectively, and are not repeated herein.

Referring to FIGS. 29A and 29B, the polymer layers 626 and horizontal portions of the cover spacers 628 are removed, in accordance with some embodiments. The methods used in removing the polymer layers 626 and the horizontal portions of the cover spacers 628 are the same as or similar to those of removing the polymer layers 126 and the horizontal portions of the cover spacers 128, and are not repeated herein.

In some embodiments, the remained vertical portions of the cover spacers 628 still cover the sidewalls of the gate spacers 120, the semiconductor layers 108B, the semiconductor layers 106A between the semiconductor layers 108B, and upper portion of the semiconductor layer 106B, so that lower portion of the semiconductor layer 106B and the semiconductor layers 106A below the topmost semiconductor layer 108A are exposed in the source/drain trenches 122, as shown in FIG. 29B.

Still referring to FIGS. 29A and 29B, the semiconductor layers 106 exposed in the source/drain trenches 122 are partially recessed by a selective etching process, in accordance with some embodiments. More specifically, the selective etching process selectively etches the side portions of the semiconductor layers 106 exposed in the source/drain trenches 122, with minimal etching (or substantially no etching) of semiconductor layers 108. After the selective etching process, the semiconductor layers 106 exposed in the source/drain trenches 122 are partially etched to form recesses 618A, as shown in FIG. 29B.

Referring to FIGS. 30A and 30B, the cover spacers 628 are removed, in accordance with some embodiments. The method used in removing the cover spacers 628 is the same as or similar to those of removing the cover spacers 128, and is not repeated herein. After removing the cover spacers 628, the semiconductor layers 106 and 108 (including recesses 618A) are exposed in the source/drain trenches 122.

Still referring to FIGS. 30A and 30B, the semiconductor layers 106 exposed in the source/drain trenches 122 are partially recessed by a selective etching process, in accordance with some embodiments. Specifically, the selective etching process is performed that selectively etches the side portions of the semiconductor layers 106 below the gate spacers 120 through the source/drain trenches 122, with minimal etching (or substantially no etching) of semiconductor layers 108.

After the selective etching process, the semiconductor layers 106A between the semiconductor layers 108B and the upper portion of the semiconductor layer 106B are partially etched to form inner spacer recesses 620C, as shown in FIG. 30B. Moreover, the semiconductor layers 106A below the topmost semiconductor layer 108A and the lower portion of the semiconductor layer 106B are partially etched, so that the recesses 618A are further etched to form inner spacer recesses 620A, as shown in FIG. 30B. In some embodiments, the inner spacer recesses 620A over the topmost semiconductor layer 108A and the inner spacer recesses 620C below the bottommost semiconductor layer 108B may constitute inner spacer recesses 620B. Since the inner spacer recesses 620A undergo more etching process than the inner spacer recesses 620C, the horizontal dimensions of the inner spacer recesses 620A are greater than the horizontal dimensions of the inner spacer recesses 620C in the X-direction, as shown in FIG. 30B.

Referring to FIGS. 31A and 31B, inner spacers 624A, 624B, and 624C (which may be collectively referred to as inner spacers 624) are formed in the inner spacer recesses 620A, 620B, and 620C, respectively, in accordance with some embodiments. Specifically, the inner spacers 624A may be formed in the inner spacer recesses 620A that are between the semiconductor layers 108A and between the semiconductor layer 108A and the substrate 102. The inner spacers 624B may include first portions 624B1 formed in the inner spacer recesses 620A that are over the topmost semiconductor layer 108A, and second portions 624B2 formed in the inner spacer recesses 620C that are below the bottommost semiconductor layer 108B. The inner spacers 624C may be formed in the inner spacer recesses 620C between the semiconductor layers 108B. The material and method used in forming the inner spacers 624 are the same as or similar to those of the inner spacers 124, and are not repeated herein.

Since the horizontal dimensions of the inner spacer recesses 620A and 620C are different in the X-direction, the horizontal dimensions of the inner spacers 624A, 624B, and 624C formed in the inner spacer recesses 620A and 620C are different in the X-direction. In some embodiments, the inner spacers 624A and the first portions 624B1 of the inner spacers 624B have a thickness T12 in the X-direction, and the inner spacers 624C and the second portions 624B2 of the inner spacers 624B have a thickness T13 in the X-direction. In some embodiments, the thickness T12 is greater than the thickness T13 by about 0.5 nm to about 4 nm. In some embodiments, the gate spacers 120 have the thickness T3 in the X-direction, and the thickness T3 is greater than the thickness T12 by about 0.5 nm to about 4 nm.

Referring to FIGS. 32A and 32B, the bottom isolation layers 130 and the source/drain features 132A are formed in the lower parts of the source/drain trenches 122, in accordance with some embodiments. The formation of the bottom isolation layers 130 and the source/drain features 132A may include forming the polymer layer 126 and the cover spacers 128 and removing the polymer layer 126 and the horizontal portions of the cover spacers 128, which have been discussed above with reference to FIGS. 7A to 8B, and are not repeated herein.

Then, the bottom isolation layers 130 and the source/drain features 132A may be formed in the lower parts of the source/drain trenches 122, while the sidewalls of the gate spacers 120 and the semiconductor layers 108B are covered by the cover spacers 128. The materials and methods used in forming the bottom isolation layers 130 and the source/drain features 132A have been discussed above with reference to FIGS. 10A and 10B, and are not repeated herein.

Still referring to FIGS. 32A and 32B, the cover spacers 128 are removed through a selective etching process, and then the ILD layer 134 is formed in the source/drain trenches 122, in accordance with some embodiments. The method used in removing cover spacers 128 and the material and method used in forming the ILD layer 134 have been discussed above with reference to FIGS. 11A and 11B, and are not repeated herein.

Still referring to FIGS. 32A and 32B, the source/drain features 132B are formed in the source/drain trenches 122 and over the ILD layer 134, in accordance with some embodiments. The material and method used in forming the source/drain features 132B have been discussed above with reference to FIGS. 12A and 12B, and are not repeated herein.

In some embodiments, since the inner spacers 624 are not recessed through the source/drain trenches 122, the sidewalls of the inner spacers 624A, 624B, and 624C are aligned with each other and the sidewalls of the gate spacers 120 and the semiconductor layers 108, as shown in FIG. 32B. In some embodiments, the source/drain features 132A are in contact with the inner spacers 624A and the first portions 624B1 of the inner spacers 624B, and the source/drain features 132B are in contact with the inner spacers 624C and the second portions 624B2 of the inner spacers 624B.

Still referring to FIGS. 32A and 32B, the CESLs 136 are formed over the source/drain features 132B and the ILD layer 134, and the ILD layer 138 is formed over the CESLs 136 to fill the spaces between the source/drain features 132B, in accordance with some embodiments. The material and method used in forming the CESLs 136 and the ILD layer 138 have been discussed above with reference to FIGS. 12A and 12B, and are not repeated herein.

Referring to FIGS. 33A and 33B, the dummy gate structure 114 and the semiconductor layers 106 are removed to form a gate trench, and a gate structure 642 including a gate structure 642A and a gate structure 642B is formed in the gate trench, in accordance with some embodiments. The methods used in removing the dummy gate structure 114 and the semiconductor layers 106 to form the gate trench are the same as or similar to those of forming the gate trench 140, and are not repeated herein.

In some embodiments, the gate structure 642B is over the gate structure 642A. In some embodiments, the gate structure 642A includes a gate dielectric layer 644A and a gate electrode layer 646A, and the gate structure 642B includes a gate dielectric layer 644B and a gate electrode layer 646B. The materials and methods used in forming the gate dielectric layers 644A and 644B and the gate electrode layers 646A and 646B are the same as or similar to those of the gate dielectric layers 144A and 144B and the gate electrode layers 146A and 146B, respectively, and are not repeated herein.

In some embodiments, the gate dielectric layer 644A wraps around each of the semiconductor layers 108A, and the gate electrode layer 646A wraps around the gate dielectric layers 644A. Moreover, the gate dielectric layer 644A is also formed on the sidewalls of the inner spacers 624A and the first portions 624B1 of the inner spacers 624B, as well as over the top surfaces of the substrate 102 and the isolation structures 104. In some embodiments, the gate dielectric layer 644B wraps around each of the semiconductor layers 108B, and the gate electrode layer 646B wraps around the gate dielectric layer 644B. Moreover, the gate dielectric layer 644B is also formed on the sidewalls of the inner spacers 624C, the second portions 624B2 of the inner spacers 624B, and the gate spacers 120. In some embodiments, the gate dielectric layer 644B is in contact with top surfaces of the first portions 624B1 of the inner spacers 624B, wherein these top surfaces are generated due to the difference of horizontal dimensions between the first portions 624B1 and the second portions 624B2.

Similar to the gate structure 142, the gate structure 642A may be referred to as first inner gate structure, and the gate structure 642B may be divided into an outer gate structure and a second inner gate structure. The gate structure 642A may be in contact with the inner spacers 624A and first portions 624B1 of the inner spacers 624B. The outer gate structure of the gate structure 642B may be in contact with the gate spacers 120, and the second inner gate structure of the gate structure 642B may be in contact with the inner spacers 624C and the second portions 624B2 of the inner spacers 624B.

In some embodiments, in the X-direction, the gate structure 642A (first inner gate structure) has a width W10, the second inner gate structure of the gate structure 642B has a width W11, and the outer gate structure of the gate structure 642B has a width W12, as shown in FIG. 33B. In some embodiments, the width W11 is greater than the width W10 by about 0.5 nm to about 4 nm. In some embodiments, the width W10 is greater than the width W12 by about 0.5 nm to about 4 nm. In some embodiments, the width W12 is smaller than the width W10 and/or the width W11 by about 0.5 nm to about 8 nm.

After forming the gate structure 642, the transistors in the CFET are formed. For example, in the workpiece 600, the source/drain features 132A1 and 132A2, the semiconductor layers 108A, and the gate structures 642A constitute the transistor 650A, and the source/drain features 132B1 and 132B2, the semiconductor layers 108B, and the gate structures 642B constitute the transistor 650B over the transistor 650A, as shown in FIGS. 33A and 33B. One transistor 650A and one transistor 650B constitute a CFET. In some embodiments, the workpiece 600 includes two CFETs, for example, FIGS. 33A and 33B show the CFET 600A and a CFET 600B. In some embodiments, the transistors 650A and 650B are PFET and NFET in the CFET, respectively. In other embodiments, the transistors 650A and 650B are NFET and PFET in the CFET, respectively.

In some embodiments, the inner spacers of the transistor 650B (i.e., the inner spacers 624C and the second portions 624B2 of the inner spacers 624B) have the thickness T13 that is thinner than the thickness T12 of the inner spacers of the transistor 650A (i.e., the inner spacers 624A and the first portions 624B1 of the inner spacers 624B) (see FIG. 31B). In the embodiments where the transistor 650A is PFET and the transistor 650B is NFET, the thinner thickness T13 may improve DC performance of the NFET (i.e., the transistor 650B), and the thicker thickness T12 may reduce the parasitic capacitance of the PFET (i.e., the transistor 650A). In the embodiments where the transistor 650A is NFET and the transistor 650B is PFET, the thinner thickness T13 may improve DC performance of the PFET (i.e., the transistor 650B), and the thicker thickness T12 may reduce the parasitic capacitance of the NFET (i.e., the transistor 650A).

In the embodiments where the thickness T3 of the gate spacers 120 is greater than the thicknesses T12 and T13 of the inner spacers 624, the parasitic capacitance of the CFET can be reduced further. In the embodiments where the k value of the gate spacers 120 is lower than the inner spacers 624, the parasitic capacitance of the CFET can be reduced further. In some embodiments, the material of the inner spacers 624C is different from that of the inner spacers 624A. For example, the k value of the inner spacers 624A is lower when the transistor 650A is PFET, alternatively, the k value of the inner spacers 624C is lower when the transistor 650B is PFET.

In some embodiments, the inner gate structure of the transistor 650B (i.e., the second inner gate structure of the gate structure 642B) have the width W11 that is wider than the width W10 of the inner gate structure of the transistor 650A (i.e., the gate structure 642A), as shown in FIG. 33B. In the embodiments where the transistor 650A is PFET and the transistor 650B is NFET, the wider width W11 may mitigate DIBL of the NFET (i.e., the transistor 650B). In the embodiments where the transistor 650A is NFET and the transistor 650B is PFET, the wider width W11 may mitigate DIBL of the PFET (i.e., the transistor 650B).

Still referring to FIGS. 33A and 33B, the interconnection structure is formed in the workpiece 600, in accordance with some embodiments. For example, source/drain contacts 152 and 154 are formed on the frontside of the workpiece 600, and the source/drain contact 156 is formed on the backside of the workpiece 600. The methods used in forming the source/drain contacts 152, 154, and 156 have been discussed above with reference to FIGS. 15A and 15B, and are not repeated herein.

FIGS. 34A to 40B illustrate the workpiece 700 at various fabrication stages, in accordance with some alternative embodiments of the present disclosure. FIGS. 34A, 35A, 36A, 37A, 38A, 39A, and 40A are Y-Z cross-sectional views of the workpiece 700 at fabrication stages along line A-A′ of FIG. 2, in accordance with some embodiments. FIGS. 34B, 35B, 36B, 37B, 38B, 39B, and 40B are X-Z cross-sectional views of the workpiece 700 at various fabrication stages along line B-B′ of FIG. 2, in accordance with some embodiments. Similar to the workpiece 100, the workpiece 700 may be referred to as semiconductor structure 700. The fabrication stage shown in FIGS. 34A and 34B follows the fabrication stage shown in FIGS. 5A and 5B.

Referring to FIGS. 34A and 34B, polymer layers 726 and cover spacers 728 are formed in the source/drain trenches 122, in accordance with some embodiments. More specifically, the cover spacers 728 are first conformally formed in the source/drain trenches 122 to cover the sidewalls of the semiconductor layers 106 and 108 and gate spacers 120. Then, the polymer layers 726 are formed in lower parts of the source/drain trenches 122 and on the surfaces of the cover spacers 728. In some embodiments, the formation of the polymer layers 726 is configured to obtain the polymer layers 726 with desired height. For example, top surfaces of the polymer layers 726 are lower than the semiconductor layers 108B and higher than the semiconductor layers 108A, as shown in FIG. 34B. The materials and methods used in forming the polymer layers 726 and the cover spacers 728 are the same as or similar to those of the polymer layers 126 and the cover spacers 128, respectively, and are not repeated herein.

Referring to FIGS. 35A and 35B, the cover spacers 728 are etched back, such that the top surfaces of the cover spacers 728 and the polymer layers 726 are at the same level in the Z-direction, in accordance with some embodiments. For example, a selective etching process is performed that selectively etches the cover spacers 728, with minimal etching (or substantially no etching) of the gate spacers 120, the semiconductor layers 106 and 108, and the polymer layers 726.

Referring to FIGS. 36A and 36B, the polymer layers 726 are removed, in accordance with some embodiments. More specifically, a selective etching process is performed that selectively etches the polymer layers 726, with minimal etching (or substantially no etching) of the semiconductor layers 108 and 106 and the gate spacers 120. In some embodiments, after removing the polymer layers 726, the remained cover spacers 728 cover the sidewalls of the semiconductor layers 106A below the topmost semiconductor layer 108A and lower portion of the semiconductor layer 106B, so that the semiconductor layers 106A between the semiconductor layers 108B and upper portion of the semiconductor layer 106B are exposed in the source/drain trenches 122, as shown in FIG. 36B.

Still referring to FIGS. 36A and 36B, the semiconductor layers 106 exposed in the source/drain trenches 122 are partially recessed by a selective etching process, in accordance with some embodiments. More specifically, the selective etching process selectively etches the side portions of the semiconductor layers 106 exposed in the source/drain trenches 122, with minimal etching (or substantially no etching) of semiconductor layers 108 and the gate spacers 120. After the selective etching process, the semiconductor layers 106 exposed in the source/drain trenches 122 are partially etched to form recesses 718C, as shown in FIG. 36B.

Referring to FIGS. 37A and 37B, the cover spacers 728 are removed, in accordance with some embodiments. The method used in removing the cover spacers 728 is the same as or similar to those of removing the cover spacers 128, and is not repeated herein. After removing cover spacers 728, the semiconductor layers 106 and 108 (including recesses 718C) are exposed in the source/drain trenches 122.

Still referring to FIGS. 37A and 37B, the semiconductor layers 106 exposed in the source/drain trenches 122 are partially recessed by a selective etching process, in accordance with some embodiments. More specifically, the selective etching process is performed that selectively etches the side portions of the semiconductor layers 106 below the gate spacers 120 through the source/drain trenches 122, with minimal etching (or substantially no etching) of semiconductor layers 108.

After the selective etching process, the semiconductor layers 106A below the topmost semiconductor layers 108A and the lower portion of the semiconductor layer 106B are partially etched to form inner spacer recesses 720A. Moreover, the semiconductor layers 106A between the semiconductor layer 108B and the upper portion of the semiconductor layer 106B are partially etched, so that the recesses 718C are further etched to form inner spacer recesses 720C, as shown in FIG. 37B. In some embodiments, the inner spacer recesses 720A over the topmost semiconductor layer 108A and the inner spacer recesses 720C below the bottommost semiconductor layer 108B may constitute inner spacer recesses 620B. Since the inner spacer recesses 720C undergo more etching process than the inner spacer recesses 720A, the horizontal dimensions of the inner spacer recesses 720C are greater than the horizontal dimensions of the inner spacer recesses 720A in the X-direction, as shown in FIG. 37B.

Referring to FIGS. 38A and 38B, inner spacers 724A, 724B, and 724C (may be collectively referred to as inner spacers 624) are formed in the inner spacer recesses 720A, 720B, and 720C, respectively, in accordance with some embodiments. More specifically, the inner spacers 724A may be formed in the inner spacer recesses 720A that are between the semiconductor layers 108A and between the semiconductor layer 108A and the substrate 102. The inner spacers 724B may include first portions 724B1 formed in the inner spacer recesses 720A that are over the topmost semiconductor layer 108A, and second portions 724B2 formed in the inner spacer recesses 720C that are below the bottommost semiconductor layer 108B. The inner spacers 724C may be formed in the inner spacer recesses 720C between the semiconductor layers 108B. The material and method used in forming the inner spacers 724 are the same as or similar to those of the inner spacers 124, and are not repeated herein.

Since the horizontal dimensions of the inner spacer recesses 720A and 720C are different in the X-direction, the horizontal dimensions of the inner spacers 724A, 724B, and 724C formed in the inner spacer recesses 720A and 720C are different in the X-direction. In some embodiments, the inner spacers 724A and the first portions 724B1 of the inner spacers 724B have a thickness T14 in the X-direction, and the inner spacers 724C and the second portions 724B2 of the inner spacers 724B have a thickness T15 in the X-direction. In some embodiments, the thickness T15 is greater than the thickness T14 by about 0.5 nm to about 4 nm. In some embodiments, the gate spacers 120 have the thickness T3 in the X-direction, and the thickness T3 is greater than the thickness T15 by about 0.5 nm to about 4 nm.

Referring to FIGS. 39A and 39B, the bottom isolation layers 130 and the source/drain features 132A are formed in the lower parts of the source/drain trenches 122, in accordance with some embodiments. The formation of the bottom isolation layers 130 and the source/drain features 132A may include forming the polymer layer 126 and the cover spacers 128 and removing the polymer layer 126 and the horizontal portions of the cover spacers 128, which have been discussed above with reference to FIGS. 7A to 8B, and are not repeated herein.

Then, the bottom isolation layers 130 and the source/drain features 132A may be formed in the lower parts of the source/drain trenches 122, while the sidewalls of the gate spacers 120 and the semiconductor layers 108B are covered by the cover spacers 128. The materials and methods used in forming the bottom isolation layers 130 and the source/drain features 132A have been discussed above with reference to FIGS. 10A and 10B, and are not repeated herein.

Still referring to FIGS. 39A and 39B, the cover spacers 128 are removed through a selective etching process, and then the ILD layer 134 is formed in the source/drain trenches 122, in accordance with some embodiments. The method used in removing cover spacers 128 and the material and method used in forming the ILD layer 134 have been discussed above with reference to FIGS. 11A and 11B, and are not repeated herein.

Still referring to FIGS. 39A and 39B, the source/drain features 132B are formed in the source/drain trenches 122 and over the ILD layer 134, in accordance with some embodiments. The material and method used in forming the source/drain features 132B have been discussed above with reference to FIGS. 12A and 12B, and are not repeated herein.

In some embodiments, since the inner spacers 724A, 724B, and 724C are not recessed through the source/drain trenches 122, the sidewalls of the inner spacers 724A, 724B, and 724C are aligned with each other and the sidewalls of the gate spacers 120 and the semiconductor layers 108, as shown in FIG. 39B. In some embodiments, the source/drain features 132A are in contact with the inner spacers 724A and the first portions 724B1 of the inner spacers 724B. In some embodiments, the source/drain features 132B are in contact with the inner spacers 724C and the second portions 724B2 of the inner spacers 724B.

Still referring to FIGS. 39A and 39B, the CESLs 136 are formed over the source/drain features 132B and the ILD layer 134, and the ILD layer 138 is formed over the CESLs 136 to fill the spaces between the source/drain features 132B, in accordance with some embodiments. The material and method used in forming the CESLs 136 and the ILD layer 138 have been discussed above with reference to FIGS. 12A and 12B, and are not repeated herein.

Referring to FIGS. 40A and 40B, the dummy gate structure 114 and the semiconductor layers 106 are removed to form a gate trench, and gate structure 742 including a gate structure 742A and a gate structure 742B is formed in the gate trench, in accordance with some embodiments. The methods used in removing the dummy gate structure 114 and the semiconductor layers 106 to form the gate trench are the same as or similar to those of forming the gate trench 140, and are not repeated herein.

In some embodiments, the gate structure 742B is over the gate structure 742A. In some embodiments, the gate structure 742A includes a gate dielectric layer 744A and a gate electrode layer 746A, and the gate structure 742B includes a gate dielectric layer 744B and a gate electrode layer 746B. The materials and methods used in forming the gate dielectric layers 744A and 744B and the gate electrode layers 746A and 746B are the same as or similar to those of the gate dielectric layers 144A and 144B and the gate electrode layers 146A and 146B, respectively, and are not repeated herein.

In some embodiments, the gate dielectric layer 744A wraps around each of the semiconductor layers 108A, and the gate electrode layer 746A wraps around the gate dielectric layers 744A. Moreover, the gate dielectric layer 744A is also formed on the sidewalls of the inner spacers 724A and the first portions 724B1 of the inner spacers 724B, as well as over the top surfaces of the substrate 102 and the isolation structures 104. In some embodiments, the gate dielectric layer 744A is in contact with bottom surfaces of the second portions 724B2 of the inner spacers 724B, wherein these bottom surfaces are generated due to the difference of horizontal dimensions between the first portions 724B1 and the second portions 724B2. In some embodiments, the gate dielectric layer 744B wraps around each of the semiconductor layers 108B, and the gate electrode layer 746B wraps around the gate dielectric layer 744B. Moreover, the gate dielectric layer 744B is also formed on the sidewalls of the inner spacers 724C, the second portions 724B2 of the inner spacers 724B, and the gate spacers 120.

Similar to the gate structure 142, the gate structure 742A may be referred to as first inner gate structure, and the gate structure 742B may be divided into an outer gate structure and a second inner gate structure. The gate structure 742A may be in contact with the inner spacers 724A and first portions 724B1 of the inner spacers 724B. The outer gate structure of the gate structure 742B may be in contact with the gate spacers 120, and the second inner gate structure of the gate structure 742B may be in contact with the inner spacers 724C and the second portions 724B2 of the inner spacers 724B.

In some embodiments, in the X-direction, the gate structure 742A (first inner gate structure) has a width W13, the second inner gate structure of the gate structure 742B has a width W14, and the outer gate structure of the gate structure 742B has a width W15, as shown in FIG. 40B. In some embodiments, the width W13 is greater than the width W14 by about 0.5 nm to about 4 nm. In some embodiments, the width W14 is greater than the width W15 by about 0.5 nm to about 4 nm. In some embodiments, the width W15 is smaller than the width W13 and/or the width W14 by about 0.5 nm to about 8 nm.

After forming the gate structure 742, the transistors in the CFET are formed. For example, in the workpiece 700, the source/drain features 132A1 and 132A2, the semiconductor layers 108A, and the gate structures 742A constitute the transistor 750A, and the source/drain features 132B1 and 132B2, the semiconductor layers 108B, and the gate structures 742B constitute the transistor 750B over the transistor 750A, as shown in FIGS. 40A and 40B. One transistor 750A and one transistor 750B constitute a CFET. In some embodiments, the workpiece 700 includes two CFETs, for example, FIGS. 40A and 40B show a CFET 700A and a CFET 700B. In some embodiments, the transistors 750A and 750B are PFET and NFET in the CFET, respectively. In other embodiments, the transistors 750A and 750B are NFET and PFET in the CFET, respectively.

In some embodiments, the inner spacers of the transistor 750A (i.e., the inner spacers 724A and the first portions 724B1 of the inner spacers 724B) have the thickness T14 that is thinner than the thickness T15 of the inner spacers of the transistor 750B (i.e., the inner spacers 724C and the second portions 724B2 of the inner spacers 724B) (see FIG. 38B). In the embodiments where the transistor 750A is PFET and the transistor 750B is NFET, the thinner thickness T14 may improve DC performance of the PFET (i.e., the transistor 750A), and the thicker thickness T15 may reduce the parasitic capacitance of the NFET (i.e., the transistor 750B). In the embodiments where the transistor 750A is NFET and the transistor 750B is PFET, the thinner thickness T14 may improve DC performance of the NFET (i.e., the transistor 750A), and the thicker thickness T15 may reduce the parasitic capacitance of the PFET (i.e., the transistor 750B).

In some embodiments, the thickness T3 of the gate spacers 120 is greater than the thicknesses T14 and T15 to reduce the parasitic capacitance of the CFET further. In some embodiments, the k value of the gate spacers 120 is lower than the inner spacers 724 to reduce the parasitic capacitance of the CFET further. In some embodiments, the material of the inner spacers 724C is different from that of the inner spacers 724A. For example, the k value of the inner spacers 724A is lower when the transistor 750A is PFET, alternatively, the k value of the inner spacers 724C is lower when the transistor 750B is PFET.

In some embodiments, the inner gate structure of the transistor 750A (i.e., the gate structure 742A) have the width W13 that is wider than the width W14 of the inner gate structure of the transistor 750B (i.e., the second inner gate structure of the gate structure 742B), as shown in FIG. 40B. In the embodiments where the transistor 750A is PFET and the transistor 750B is NFET, the wider width W13 may mitigate DIBL of the PFET (i.e., the transistor 750A). In the embodiments where the transistor 750A is NFET and the transistor 750B is PFET, the wider width W13 may mitigate DIBL of the NFET (i.e., the transistor 750A).

Still referring to FIGS. 40A and 40B, the interconnection structure is formed in the workpiece 700, in accordance with some embodiments. For example, source/drain contacts 152 and 154 are formed on the frontside of the workpiece 700, and the source/drain contact 156 is formed on the backside of the workpiece 700. The methods used in forming the source/drain contacts 152, 154, and 156 have been discussed above with reference to FIGS. 15A and 15B, and are not repeated herein.

The embodiments disclosed herein relate to semiconductor structures and their forming methods, and more particularly to methods and semiconductor structures that have thinner inner spacers for one of the PFET and NFET of the CFET for improving DC performance, and thicker inner spacers for the other one of the PFET and NFET of the CFET to reduce parasitic capacitance. Moreover, embodiments discussed herein further include methods and structures that have larger inner metal gate width for one of the PFET and NFET of the CFET to mitigate DIBL. In this way, the inner spacer thicknesses and the inner metal gate widths of PFET and NFET in the same CFET can be modified individually, and thus can be optimized individually. Furthermore, thickness of the gate spacers can be formed wider than the inner spacers of PFET and NFET to further reduce the parasitic capacitance.

In one exemplary aspect, the present disclosure is directed to a method of forming a semiconductor structure. The method includes forming a fin structure over a substrate, wherein the fin structure includes first semiconductor layers and second semiconductor layers alternately stacked; forming source/drain trenches in the fin structure; partially recessing the first semiconductor layers exposed in the source/drain trenches to form inner spacer recesses; and forming first inner spacers, second inner spacers, and third inner spacers in the inner spacer recesses. The second inner spacers are vertically sandwiched between the first inner spacers and the third inner spacers. The method further includes partially recessing the first inner spacers and first portions of the second inner spacers to form recessed first inner spacers and recessed first portions of the second inner spacers; and forming first source/drain features and second source/drain features in the source/drain trenches. The first source/drain features are in contact with the recessed first inner spacers and the recessed first portions of the second inner spacers. The second source/drain features are in contact with the third inner spacers and second portions of the second inner spacers.

In another exemplary aspect, the present disclosure is directed to a method of forming a semiconductor structure. The method includes forming a fin structure over a substrate, the fin structure includes a first stack and a second stack over the first stack. The first stack includes first semiconductor layers and second semiconductor layers alternately stacked, and the second stack includes third semiconductor layers and fourth semiconductor layers alternately stacked. The third semiconductor layers and the first semiconductor layers have different Ge concentrations, and the topmost one of the first semiconductor layers is in contact with the bottommost one of the third semiconductor layers. The method further includes forming source/drain trenches in the fin structure; partially recessing the first semiconductor layers and the third semiconductor layers exposed in the source/drain trenches to form first inner spacer recesses and second inner spacer recesses, respectively; and forming first inner spacers and third inner spacers in the first inner spacer recesses and the second inner spacer recesses, respectively. The first inner spacer recesses and the second inner spacer recesses have different horizontal dimensions. The first inner spacers over the topmost one of the second semiconductor layers and the third inner spacers below the bottommost one of the fourth semiconductor layers constitute second inner spacers. The method further includes forming first source/drain features in the source/drain trenches; and forming second source/drain features over the first source/drain features in the source/drain trenches. The first source/drain features are in contact with the first inner spacers and first portions of the second inner spacers, and the second source/drain features are in contact with the third inner spacers and second portions of the second inner spacers.

In yet another exemplary aspect, the present disclosure is directed to a semiconductor structure. The semiconductor structure includes a first transistor and a second transistor stacked with the first transistor. The first transistor includes first nanostructures over a substrate; first inner spacers between the first nanostructures and between a bottommost one of the first nanostructures and the substrate; and first source/drain features attached to opposite sides of the first nanostructures in an X-direction. The first nanostructures are spaced apart from each other in a Z-direction. The second transistor includes second nanostructures over the first nanostructures; second inner spacers between the second nanostructures; and second source/drain features, attached to opposite sides of the second nanostructures in the X-direction and disposed over the first source/drain features. The second nanostructures are spaced apart from each other in the Z-direction. The semiconductor structure further includes a gate structure wrapped around the first nanostructures and the second nanostructures. The first thicknesses of the first inner spacers are smaller than the second thicknesses of the second inner spacers in the X-direction.

In yet another exemplary aspect, the present disclosure is directed to a method of forming a semiconductor structure. The method includes forming a fin structure; forming source/drain trenches the fin structure; and forming cover spacers on sidewalls of the source/drain trenches. The fin structure includes a first stack, a second stack, and a third semiconductor layer vertically between the first stack and the second stack. The first stack and the second stack each includes first semiconductor layers and second semiconductor layers alternately stacked. The cover spacers cover the first stack and first portions of the third second semiconductor layer, and expose the second stack and second portions of the third semiconductor layer. The method further includes partially recessing the first semiconductor layers of the second stack and the second portions of the third semiconductor layer exposed in the source/drain trenches to form recesses; removing the cover spacers; and partially recessing the first semiconductor layers and the third semiconductor layer exposed in the source/drain trenches, so as to form first inner spacer recesses and third inner spacer recesses in the first semiconductor layers of the first stack and the second stack, respectively, and form second inner spacer recesses in the third semiconductor layer. The method further includes forming first inner spacers, second inner spacers, and third inner spacers in the first inner spacer recesses, the second inner spacer recesses, and the third inner spacer recesses, respectively; and forming first source/drain features and second source/drain features in the source/drain trenches. The first source/drain features are in contact with the first inner spacers and third portions of the second inner spacers, and the second source/drain features are in contact with the third inner spacers and fourth portions of the second inner spacers.

In some embodiments, the formation of the cover spacers includes conformally depositing spacer layers in the source/drain trenches; forming polymer layers on the spacer layers, wherein top surfaces of the polymer layers are higher than the first stack; and etching back the spacer layers into a height of the top surfaces of the polymer layers, so as to form the cover spacers.

In some embodiments, first horizontal dimensions of the third inner spacers and the second portions of the second inner spacers are greater than second horizontal dimensions of the first inner spacers and the first portions of the second inner spacers.

In some embodiments, the formation of the cover spacers includes forming polymer layers in lower parts of the source/drain trenches; conformally depositing spacer layers over the polymer layers and on sidewalls of remaining parts of the source/drain trenches; and removing the polymer layers and horizontal portions of the spacer layers to form the cover spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure over a substrate, wherein the fin structure comprises first semiconductor layers and second semiconductor layers alternately stacked;
forming source/drain trenches in the fin structure;
partially recessing the first semiconductor layers exposed in the source/drain trenches to form inner spacer recesses;
forming first inner spacers, second inner spacers, and third inner spacers in the inner spacer recesses, wherein the second inner spacers are vertically sandwiched between the first inner spacers and the third inner spacers;
partially recessing the first inner spacers and first portions of the second inner spacers to form recessed first inner spacers and recessed first portions of the second inner spacers; and
forming first source/drain features and second source/drain features in the source/drain trenches, wherein the first source/drain features are in contact with the recessed first inner spacers and the recessed first portions of the second inner spacers, and wherein the second source/drain features are in contact with the third inner spacers and second portions of the second inner spacers.

2. The method of claim 1, wherein first horizontal dimensions of the third inner spacers and the second portions of the second inner spacers are greater than second horizontal dimensions of the recessed first inner spacers and the recessed first portions of the second inner spacers.

3. The method of claim 1, further comprising:
forming cover spacers on sidewalls of source/drain trenches, wherein the cover spacers cover the third inner spacers, cover the second portions of the second inner spacers, and expose the first inner spacers and the first portions of the second inner spacers; and
partially recessing the first inner spacers and the first portions of the second inner spacers exposed by the cover spacers to form the recessed first inner spacers and the recessed first portions of the second inner spacers.

4. The method of claim 3, wherein the forming of the cover spacers further comprises:
forming polymer layers in lower parts of the source/drain trenches;
forming spacer layers over the polymer layers and on sidewalls of remaining parts of the source/drain trenches; and
removing the polymer layers and horizontal portions of the spacer layers to form the cover spacers.

5. The method of claim 1, further comprising:
forming a dummy gate structure over the fin structure, wherein the source/drain trenches are formed on opposite sides of the dummy gate structure; and
forming gate spacers on opposite sidewalls of the dummy gate structure,
wherein first horizontal dimensions of the third inner spacers are smaller than third horizontal dimensions of the gate spacers.

6. The method of claim 5, wherein a difference between the first horizontal dimensions and the third horizontal dimensions is in a range from about 0.5 nm to about 4 nm.

7. The method of claim 1, further comprising:
forming the second source/drain features in lower parts of the source/drain trenches;
forming interlayer dielectric (ILD) layers on the second source/drain features, wherein the second source/drain features and the ILD layers cover the third inner spacers, cover the second portions of the second inner spacers, and expose the first inner spacers and the first portions of the second inner spacers; and
partially recessing the first inner spacers and the first portions of the second inner spacers exposed by the second source/drain features, the ILD layers, and the source/drain trenches, so as to form the recessed first inner spacers and the recessed first portions of the second inner spacers.

8. The method of claim 1,
wherein after the partially recessing of the first inner spacers and the first portions of the second inner spacers, end portions of a first subset of the second semiconductor layers are exposed in the source/drain trenches; and
wherein the second semiconductor layers of the first subset of the second semiconductor layers are in contact with the first inner spacers or the first portions of the second inner spacers.

9. A method of forming a semiconductor structure, comprising:
forming a fin structure over a substrate, wherein the fin structure comprises a first stack and a second stack over the first stack, wherein the first stack comprises first semiconductor layers and second semiconductor layers alternately stacked, and the second stack comprises third semiconductor layers and fourth semiconductor layers alternately stacked, wherein the third semiconductor layers and the first semiconductor layers have different Ge concentrations, and wherein a topmost one of the first semiconductor layers is in contact with a bottommost one of the third semiconductor layers;
forming source/drain trenches in the fin structure;
partially recessing the first semiconductor layers and the third semiconductor layers exposed in the source/drain trenches to form first inner spacer recesses and second inner spacer recesses, respectively, wherein the first inner spacer recesses and the second inner spacer recesses have different horizontal dimensions;
forming first inner spacers and third inner spacers in the first inner spacer recesses and the second inner spacer recesses, respectively, wherein the first inner spacers over a topmost one of the second semiconductor layers and the third inner spacers below a bottommost one of the fourth semiconductor layers constitute second inner spacers;
forming first source/drain features in the source/drain trenches, wherein the first source/drain features are in contact with the first inner spacers and first portions of the second inner spacers; and
forming second source/drain features over the first source/drain features in the source/drain trenches, wherein the second source/drain features are in contact with the third inner spacers and second portions of the second inner spacers.

10. The method of claim 9,
wherein a second Ge concentration of the third semiconductor layers is greater than a first Ge concentration of the first semiconductor layers; and
wherein second horizontal dimensions of the second inner spacer recesses are greater than first horizontal dimensions of the first inner spacer recesses, such that fourth horizontal dimensions of the third inner spacers and the second portions of the second inner spacers are greater than third horizontal dimensions of the first inner spacers and the first portions of the second inner spacers.

11. The method of claim 10, wherein a difference between the third horizontal dimensions and the fourth horizontal dimensions is in a range from about 0.5 nm to about 4 nm.

12. The method of claim 11, further comprising:
forming a gate structure, wherein the gate structure comprises a first inner gate structure wrapped around the second semiconductor layers, a second inner gate structure wrapped around the fourth semiconductor layers, and an outer gate structure over a topmost one of the fourth semiconductor layers.

13. The method of claim 12, wherein a fifth horizontal dimension of the first inner gate structure is greater than a sixth horizontal dimension of the second inner gate structure, and the sixth horizontal dimension of the second inner gate structure is greater than a seventh horizontal dimension of the outer gate structure.

14. The method of claim 13, wherein the seventh horizontal dimension of the outer gate structure is smaller than the fifth horizontal dimension of the first inner gate structure by about 0.5 nm to about 8 nm.

15. The method of claim 12, further comprising:
forming gate spacers on opposite sidewalls of the gate structure,
wherein eighth horizontal dimensions of the gate spacers are greater than the fourth horizontal dimensions of the third inner spacers and the second portions of the second inner spacers.

16. The method of claim 9, further comprising:
before the forming of the first source/drain features, forming bottom isolation layers in lower parts of the source/drain trenches,
wherein the first source/drain features are formed on the bottom isolation layers.

17. A semiconductor structure, comprising:
a first transistor, comprising:
first nanostructures over a substrate, wherein the first nanostructures are spaced apart from each other in a Z-direction;
first inner spacers between the first nanostructures and between a bottommost one of the first nanostructures and the substrate; and
first source/drain features, attached to opposite sides of the first nanostructures in an X-direction;
a second transistor that is stacked with the first transistor, wherein the second transistor comprises:
second nanostructures over the first nanostructures, wherein the second nanostructures are spaced apart from each other in the Z-direction;
second inner spacers between the second nanostructures; and
second source/drain features, attached to opposite sides of the second nanostructures in the X-direction and disposed over the first source/drain features; and
a gate structure wrapped around the first nanostructures and the second nanostructures,
wherein first thicknesses of the first inner spacers are smaller than second thicknesses of the second inner spacers in the X-direction.

18. The semiconductor structure of claim 17,
wherein first end portions of the first nanostructures protrude from the first inner spacers in the X-direction and are surrounded by the first source/drain features; and
wherein second end portions of the second nanostructures are surrounded by the second inner spacers.

19. The semiconductor structure of claim 17,
wherein the gate structure comprises a first inner gate structure wrapped around the first nanostructures, a second inner gate structure wrapped around the second nanostructures, and an outer gate structure over a topmost one of the second nanostructures; and
wherein a first dimension of the first inner gate structure is greater than a second dimension of the second inner gate structure in the X-direction, and the second dimension of the second inner gate structure is greater than a third dimension of the outer gate structure in the X-direction.

20. The semiconductor structure of claim 17, further comprising:
gate spacers, formed on opposite sides of the gate structure and over a topmost one of the second nanostructures,
wherein third thicknesses of the gate spacers are greater than the second thicknesses of the second inner spacers in the X-direction.
